(19) United States
(12) Patent Application Publication
(10) Pub. No.: US 2026/0190481 A1
(43) Pub. Date: Jul. 2, 2026

(54) SEMICONDUCTOR DEVICES USING FULLY-DEPLETED SILICON-ON-INSULATOR (FDSOI) AND METHODS FOR FORMING THE SAME

(71) Applicant: Yangtze Memory Technologies Co., Ltd., Wuhan (CN)

(72) Inventors: Wenshan XU, Wuhan (CN); Xin WANG, Wuhan (CN)

(21) Appl. No.: 19/019,640

(22) Filed: Jan. 14, 2025

(30) Foreign Application Priority Data
Dec. 30, 2024 (CN) 202411978107.3

(51) Int. Cl. H10D 86/00; H01L 21/762; H10B 12/00; H10B 41/41; H10B 43/40; H10D 30/01; H10D 64/27; H10D 64/66; H10D 86/01

(52) U.S. Cl. CPC H10D 86/201; H10D 30/027; H10D 64/514; H10D 64/661; H10D 86/01; H10P 90/1906; H10P 90/1908; H10W 10/014; H10W 10/061; H10W 10/17; H10W 10/181; H10B 12/50; H10B 41/41; H10B 43/40

(57) ABSTRACT

The present disclosure relates to methods, devices, systems, and techniques for forming semiconductor devices. An example semiconductor device includes a semiconductor layer and an insulating layer stacked on the semiconductor layer along a first direction. The semiconductor device further includes a first transistor and a second transistor. The first transistor includes a first gate structure and a first semiconductor body. The first semiconductor body is in contact with the insulating layer. The second transistor extends into the semiconductor layer along the first direction. The second transistor includes a second gate structure and a second semiconductor body. The second gate structure includes a dielectric layer aligned with the insulating layer along a second direction perpendicular to the first direction.

### CROSS-REFERENCE TO RELATED APPLICATIONS

This application claims priority to Chinese Patent Application No. 202411978107.3, filed on Dec. 30, 2024, which is hereby incorporated by reference in its entirety.

### TECHNICAL FIELD

The present disclosure relates to semiconductor devices and fabrication methods thereof.

### BACKGROUND

Silicon-on-insulator (SOI) technology can be used to build transistors on an active layer of silicon that is separated from a main silicon substrate by an insulating layer. The insulating layer can electrically isolate the active silicon layer from the main silicon substrate. Fully depleted silicon-on-insulator (FDSOI) is a type of SOI technology where the active silicon layer is made very thin, allowing the entire active silicon layer to be fully depleted of charge carriers. The FDSOI structure can enable precise control over a transistor's channel and make the transistor efficient and well-suited for low-power and high-performance applications.

### SUMMARY

The present disclosure describes methods, devices, systems, and techniques forming semiconductor devices using fully-depleted silicon-on-insulator (FDSOI).

One aspect of the present disclosure features a semiconductor device. The semiconductor device includes a semiconductor layer, an insulating layer stacked on the semiconductor layer along a first direction, and a first transistor can include a first gate structure and a first semiconductor body. In some implementations, the first semiconductor body is in contact with the insulating layer. The semiconductor device can further include a second transistor extending into the semiconductor layer along the first direction. In some implementations, the second transistor can include a second gate structure and a second semiconductor body, and the second gate structure can include a dielectric layer aligned with the insulating layer along a second direction perpendicular to the first direction.

In some implementations, a size of the dielectric layer of the second gate structure along the first direction is similar to or same as a size of the insulating layer along the first direction.

In some implementations, a difference between the size of the dielectric layer of the second gate structure and the size of the insulating layer is smaller than a threshold.

In some implementations, the insulating layer has a first surface in contact with the first semiconductor body, the dielectric layer of the second gate structure has a first surface away from the second semiconductor body along the first direction, and the first surface of the insulating layer is aligned with the first surface of the dielectric layer along the second direction.

In some implementations, the insulating layer has a second surface in contact with the semiconductor layer, the dielectric layer of the second gate structure has a second surface in contact with the second semiconductor body, and the second surface of the insulating layer is aligned with the second surface of the dielectric layer along the second direction.

In some implementations, the insulating layer and the dielectric layer of the second gate structure can include a same dielectric material.

In some implementations, the second gate structure can further include a conductive layer and a doped silicon layer in contact with each other, the doped silicon layer is in contact with the dielectric layer of the second gate structure, and the doped silicon layer is between the conductive layer and the dielectric layer of the second gate structure along the first direction.

In some implementations, the conductive layer can include polysilicon, and the doped silicon layer can include silicon heavily doped using an n-type dopant.

In some implementations, the doped silicon layer has a surface in contact with the conductive layer, the first semiconductor body has a surface in contact with the first gate structure, and the surface of the doped silicon layer is aligned with the surface of the first semiconductor body along the second direction.

In some implementations, a size of the doped silicon layer along the first direction is similar to or same as a size of the first semiconductor body along the first direction.

In some implementations, the first gate structure can include a dielectric layer, and the semiconductor device can further include a third transistor including a third gate structure and a third semiconductor body. In some implementations, the third semiconductor body is in contact with the insulating layer, and the third gate structure can include a dielectric layer. A size of the dielectric layer of the second gate structure along the first direction is larger than a size of the dielectric layer of the first gate structure along the first direction, and the size of the dielectric layer of the first gate structure along the first direction is larger than a size of the dielectric layer of the third gate structure along the first direction.

Another aspect of the present disclosure features a semiconductor device. The semiconductor device includes a semiconductor layer, an insulating layer stacked on the semiconductor layer along a first direction, and a first transistor including a first gate structure and a first semiconductor body. In some implementations, the first semiconductor body is in contact with the insulating layer. The semiconductor device can further include a second transistor extending into the semiconductor layer along the first direction. In some implementations, the second transistor can include a second gate structure and a second semiconductor body, the second gate structure can include a dielectric layer in contact with the second semiconductor body, and a size of the dielectric layer of the second gate structure along the first direction is similar to or same as a size of the insulating layer along the first direction.

In some implementations, a difference between the size of the dielectric layer of the second gate structure and the size of the insulating layer is smaller than 10% of the size of the insulating layer.

Another aspect of the present disclosure features a method of forming a semiconductor device. The method includes forming a semiconductor structure that includes a first semiconductor layer and an insulating layer stacked on the first semiconductor layer along a first direction. The method further includes forming a first transistor of the semiconductor device. In some implementations, the first transistor can include a first gate structure and a first semiconductor body, and the first semiconductor body is in contact with a first portion of the insulating layer. The method can further include forming a second transistor of the semiconductor device. In some implementations, the second transistor can include a second gate structure and a second semiconductor body, the second gate structure can include a second portion of the insulating layer, the second semiconductor body can include a portion of the first semiconductor layer, and the second portion of the insulating layer is aligned with the first portion of the insulating layer along a second direction perpendicular to the first direction.

In some implementations, a size of the first portion of the insulating layer along the first direction is similar to or same as a size of the second portion of the insulating layer along the first direction. The semiconductor structure can further include a second semiconductor layer stacked on the insulating layer. The method can further include forming a polysilicon layer stacked over the insulating layer.

In some implementations, forming the first transistor can include forming a conductive layer of the first gate structure from a first portion of the polysilicon layer and forming the first semiconductor body from a first portion of the second semiconductor layer. In some implementations, forming the second transistor can include: forming a conductive layer of the second gate structure from a second portion of the polysilicon layer; forming a dielectric layer of the second gate structure from the second portion of the insulating layer; and forming the second semiconductor body from a portion of the first semiconductor layer.

In some implementations, the method further includes depositing a high-K dielectric layer in contact with the first portion of the second semiconductor layer. Forming the polysilicon layer stacked over the insulating layer can include depositing the polysilicon layer in contact with both a second portion of the second semiconductor layer and the high-k dielectric layer.

In some implementations, the method further includes partially removing the polysilicon layer, the second semiconductor layer, and the high-K dielectric layer by an etching process. A remaining portion of the polysilicon layer can include the first portion of the polysilicon layer and the second portion of the polysilicon layer. A remaining portion of the second semiconductor layer can include the first portion of the second semiconductor layer and the second portion of the second semiconductor layer. The first gate structure can further include a dielectric layer that is in contact with the conductive layer of the first gate structure and is formed from a remaining portion of the high-k dielectric layer. The second gate structure can further include the second portion of the second semiconductor layer between the second portion of the polysilicon layer and the second portion of the insulating layer.

In some implementations, the method further includes removing a second portion of the second semiconductor layer that is in contact with the second portion of the insulating layer, and depositing a high-K dielectric layer in contact with both the second portion of the insulating layer and the first portion of the second semiconductor layer. Forming the polysilicon layer stacked over the insulating layer can include depositing the polysilicon layer on the high-k dielectric layer.

In some implementations, the method further includes partially removing the polysilicon layer and the high-K dielectric layer by an etching process. A remaining portion of the polysilicon layer can include the first portion of the polysilicon layer and the second portion of the polysilicon layer. A remaining portion of the high-k dielectric layer can include a first portion of the high-k dielectric layer and a second portion of the high-k dielectric layer. The first gate structure can further include a dielectric layer that is in contact with the conductive layer of the first gate structure and is formed from the first portion of the high-k dielectric layer. The second gate structure can further include the second portion of the high-k dielectric layer between the second portion of the polysilicon layer and the second portion of the insulating layer.

### BRIEF DESCRIPTION OF DRAWINGS

FIG. 1 illustrates a side view of an example semiconductor device.

FIG. 2 illustrates a side view of another example semiconductor device.

FIGS. 3A-3O illustrate an example process of fabricating a semiconductor device.

FIGS. 4A-4J illustrate another example process of fabricating a semiconductor device.

FIG. 5 illustrates a flow chart of an example method of fabricating a semiconductor device.

FIG. 6 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for cheaper memory devices with a higher density, a memory device (e.g., a 3D NAND flash memory) can be formed to have a large number of layers and a high aspect ratio. For example, the memory device can have multiple decks, and each deck can have multiple layers. As the number of stacked decks and layers in memory devices increases, the available area (also referred to as a peripheral boundary (PB) region) for peripheral circuits (e.g., complementary metal-oxide-semiconductor (CMOS) circuits) decreases, which may introduce challenges in device scaling and power management.

One challenge is that as the PB region shrinks, transistors of the peripheral circuits can have narrower gate widths (e.g., below 0.1 micrometers (μm)) and shorter gate lengths (e.g., below 90 nanometers (nm)). This reduction in dimensions may cause leakage currents and thus may demand advanced techniques, such as fin field-effect transistor (FinFET) and fully depleted silicon-on-insulator (FDSOI), to achieve an improved I_{ON}/I_{OFF} ratio. In addition to leakage control, there is a need for higher I/O speeds, especially for CMOS circuits. Compared with traditional silicon structures, in some implementations, transistors using FDSOI technique can achieve faster response times and reduced static power consumption. Nonetheless, high voltage (HV) devices (e.g., operating at around 30 volts (V)) may need deeper junctions to withstand such voltages, and thus may not be compatible with FDSOI. Therefore, techniques that enable manufacturing both HV devices and low voltage (LV) devices using FDSOI are desired.

In some implementations, to solve one or more of the above issues, buried oxide in an SOI can be used as HV gate oxide (HVGOX). In one or more implementations of the present disclosure, an example semiconductor device is provided. The semiconductor device includes a semiconductor layer and an insulating layer stacked on the semiconductor layer along a first direction. The semiconductor device further includes a first transistor and a second transistor. The first transistor includes a first gate structure and a first semiconductor body. The first semiconductor body is in contact with the insulating layer. The second transistor extends into the semiconductor layer along the first direction. The second transistor includes a second gate structure and a second semiconductor body. The second gate structure includes a dielectric layer aligned with the insulating layer along a second direction perpendicular to the first direction.

Implementations of the present disclosure can provide one or more of the following technical advantages and/or benefits. First, HV devices and LV devices can be integrated in the same semiconductor structure using FDSOI techniques without significant process adjustments. Second, FDSOI techniques can reduce the I_{OFF} of LV and HV devices, which facilitates the continued downsizing of CMOS circuits. Third, this approach not only enhances the performance of LV devices but also circumvents the need for extensive silicon consumption associated with HVGOX growth, thus addressing compatibility issues between HV devices and FDSOI. Fourth, the described techniques are cost-effective and can simplify the fabrication process. Fifth, using polysilicon (e.g., as a conductive material), heavy-doped silicon, and buried oxide (e.g., as gate oxide) as gate materials, gate thickness of HV devices can be customized to a reasonable value based on the requirements. Sixth, the buried oxide layer remains undisturbed, thereby minimizing the impact of stress.

The techniques can be applied to any semiconductor structures or devices that are configured to avoid electric leakage or breakdown, e.g., between conductive layers or components. The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

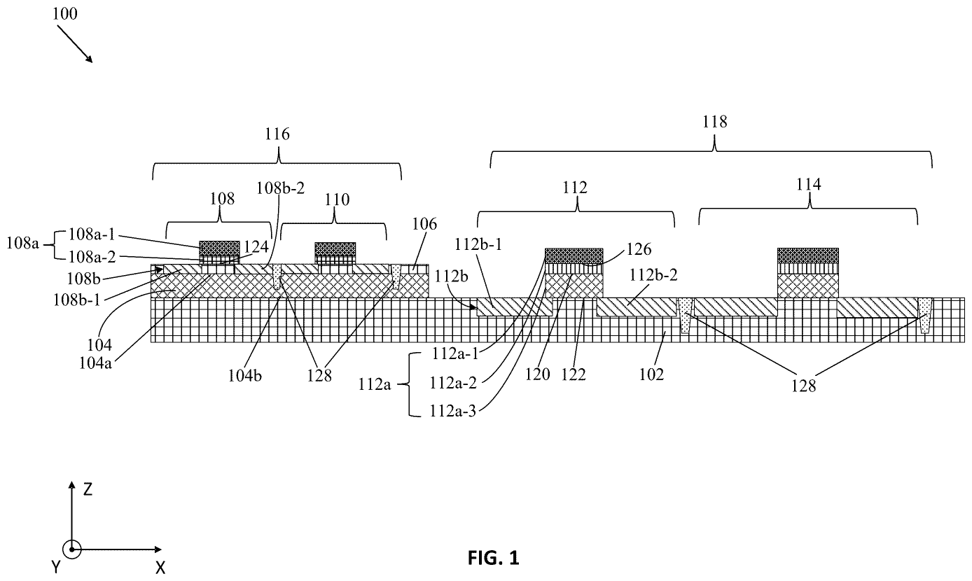

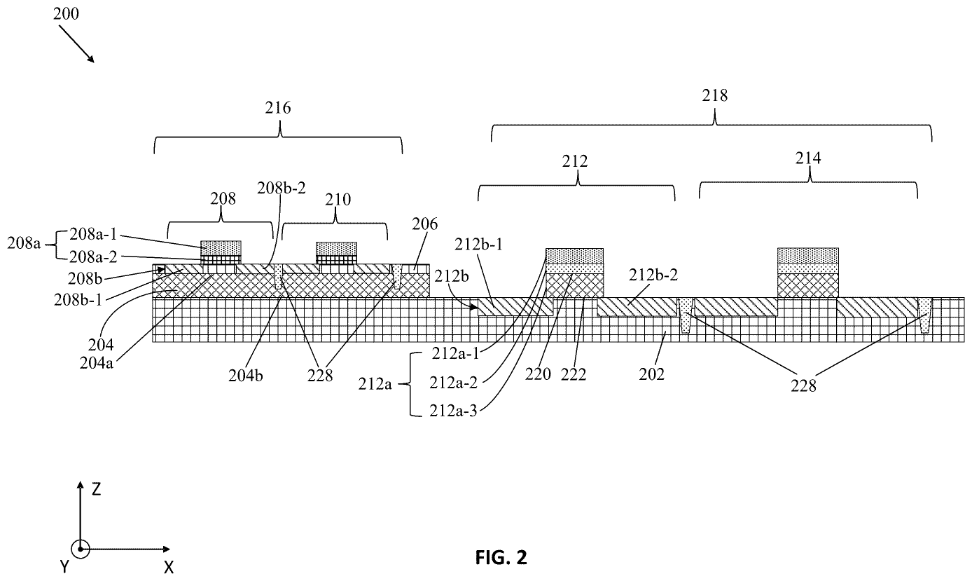

It is noted that X, Y, and Z axes (also referred to as X, Y, and Z directions) are included in FIGS. 1-2 to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1 illustrates a side view of an example semiconductor device 100. The semiconductor device 100 includes a semiconductor layer 102, an insulating layer 104, and a semiconductor layer 106. The insulating layer 104 and the semiconductor layer 106 are stacked on a portion of the semiconductor layer 102 along a vertical direction (e.g., the Z direction). Each of the semiconductor layers 102 and 106 can be any suitable semiconductor substrate having any suitable semiconductor material, such as monocrystalline, polycrystalline, or single crystalline semiconductor. For example, each of the semiconductor layers 102 and 106 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. The insulating layer 104 can include a dielectric material, such as silicon oxide, silicon nitride, silicon oxynitride, or any combination thereof.

The semiconductor device 100 further includes a transistor 108 and a transistor 112. The transistor 108 can be a field-effect transistor (FET). In the example of FIG. 1, the transistor 108 can be referred to as a fully depleted silicon-on-insulator (FDSOI) transistor. The transistor 108 can include a gate structure 108a and a semiconductor body 108b. The semiconductor body 108b can extend into the semiconductor layer 106 (e.g., along the Z direction). The semiconductor body 108b can be formed by doping a portion of the semiconductor layer 106. In some implementations, the semiconductor body 108b can be in contact with the insulating layer 104. The gate structure 108a includes a conductive layer 108a-1 and a dielectric layer 108a-2 stacked along the Z direction. The dielectric layer 108a-2 is between the conductive layer 108a-1 and the semiconductor body 108b along the Z direction. The conductive layer 108a-1 includes a conductive material (e.g., doped polysilicon). The dielectric layer 108a-2 includes a dielectric material (e.g., silicon oxide) and can also be referred to as gate oxide.

The transistor 112 can also be a FET. The transistor 112 includes a gate structure 112a and a semiconductor body 112b. As shown in FIG. 1, the semiconductor body 112b of the transistor 112 can extend into another portion of the semiconductor layer 102 (e.g., along the Z direction). The gate structure 112a includes a conductive layer 112a-1, a semiconductor layer 112a-2, and a dielectric layer 112a-3 stacked along the Z direction. The semiconductor layer 112a-2 is between the conductive layer 112a-1 and the dielectric layer 112a-3 along the Z direction. The dielectric layer 112a-3 is between the semiconductor layer 112a-2 and the semiconductor body 112b along the Z direction. The conductive layer 112a-1 includes a conductive material (e.g., doped polysilicon). The semiconductor layer 112a-2 includes a semiconductor material (e.g., doped silicon). For example, the semiconductor layer 112a-2 includes silicon heavily doped using an N-type dopant. The dielectric layer 112a-3 (also referred to as gate oxide) includes a dielectric material (e.g., silicon oxide). The dielectric layer 112a-3 can be aligned with the insulating layer 104 along a horizontal direction (e.g., the X direction). A size of the dielectric layer 112a-3 of the gate structure 112a along the Z direction can be similar to or same as a size of the insulating layer 104 along the Z direction. In some implementations, a difference between the size of the dielectric layer 112a-3 (e.g., along the Z direction) and the size of the insulating layer 104 (e.g., along the Z direction) is smaller than a threshold. For example, the threshold can be a small percentage (e.g., 10%) of the size (e.g., along the Z direction) of the insulating layer 104.

The insulating layer 104 can have a surface 104a and a surface 104b. The surface 104a is in contact with the semiconductor body 108b. The surface 104b is in contact with the semiconductor layer 102. The dielectric layer 112a-3 of the gate structure 112a has a surface 120 away from the semiconductor body 112b along the Z direction. The surface 104a of the insulating layer 104 can be aligned with the surface 120 of the dielectric layer 112a-3 along the X direction. The dielectric layer 112a-3 has a surface 122 in contact with the semiconductor body 112b. The surface 104b of the insulating layer 104 can be aligned with the surface 122 of the dielectric layer 112a-3 along the X direction. In some implementations, the insulating layer 104 and the dielectric layer 112a-3 of the gate structure 112a can include the same dielectric material.

The semiconductor body 108b of the transistor 108 can have a surface 124 in contact with the gate structure 108a of the transistor 108. The surface 124 can also be considered as a portion of a surface of the semiconductor layer 106. The semiconductor layer 112a-2 of the transistor 112 can have a surface 126 in contact with the conductive layer 112a-1 of the transistor 112. The surface 126 of the semiconductor layer 112a-2 can be aligned with the surface 124 of the semiconductor body 108b along the X direction. In some implementations, a size of the semiconductor layer 112a-2 along the Z direction is similar to or same as a size of the semiconductor body 108b along the Z direction. That is, a difference between the size of the semiconductor layer 112a-2 (e.g., along the Z direction) and the size of the semiconductor body 108b (e.g., along the Z direction) is smaller than a threshold. For example, the threshold can be a small percentage (e.g., 10%) of the size (e.g., along the Z direction) of the semiconductor body 108b.

The semiconductor body 108b of the transistor 108 can have two terminals 108b-1 and 108b-2. The terminal 108b-1 is on a first side of the semiconductor body 108b, and the terminal 108b-2 is on a second side of the semiconductor body 108b. The first side of the semiconductor body 108b can be opposite to the second side of the semiconductor body 108b along the X direction. One of the terminals 108b-1 and 108b-2 can be a source terminal, and another of the terminals 108b-1 and 108b-2 can be a drain terminal. The semiconductor body 112b of the transistor 112 can have two terminals 112b-1 and 112b-2. The terminal 112b-1 is on a first side of the semiconductor body 112b, and the terminal 112b-2 is on a second side of the semiconductor body 112b. The first side of the semiconductor body 112b can be opposite to the second side of the semiconductor body 112b along the X direction. One of the terminals 112b-1 and 112b-2 can be a source terminal, and another of the terminals 112b-1 and 112b-2 can be a drain terminal.

In some implementations, the semiconductor device 100 further includes a transistor 110 adjacent to the transistor 108. The transistors 108 and 110 can have similar structures. The transistors 108 and 110 can be at different locations in a horizontal plane (e.g., the X-Y plane). In some implementations, source and drain terminals of the transistors 108 and 110 can be doped with suitable dopants, such that one of the transistors 108 and 110 is an N-type FET and another of the transistors 108 and 110 is a P-type FET. In this case, the transistors 108 and 110 can form a complementary metal-oxide-semiconductor (CMOS) structure 116.

In some implementations, the semiconductor device 100 further includes a transistor 114 adjacent to the transistor 112. The transistors 112 and 114 can have similar structures. The transistors 112 and 114 can be at different locations in a horizontal plane (e.g., the X-Y plane). In some implementations, source and drain terminals of the transistors 112 and 114 can be doped with suitable dopants, such that one of the transistors 112 and 114 is an n-type FET and another of the transistors 112 and 114 is a p-type FET. In this case, the transistors 112 and 114 can form a CMOS structure 118. As shown in FIG. 1, in some implementations, the transistors 108, 110, 112, and 114 can be separated by shallow trench isolations (STIs) 128.

In some implementations, a thickness of the dielectric layer 112a-3 of the transistor 112 is larger than a thickness of the dielectric layer 108a-2 of the transistor 108. In other words, a size (e.g., along the Z direction) of the dielectric layer 112a-3 of the transistor 112 is larger than a size (e.g., along the Z direction) of the dielectric layer 108a-2 of the transistor 108. As such, the transistor 112 (as well as the transistor 114 and the CMOS structure 118) can operate in a higher voltage range than the transistor 108 (as well as the transistor 110 and the CMOS structure 116). In some implementations, the transistor 108, the transistor 110, and the CMOS structure 116 can be referred to as low voltage (LV) transistors or devices and can have threshold voltages smaller than or equal to, for example, 5 volts (V). The transistor 112, the transistor 114, and the CMOS structure 118 can be referred to as high voltage (HV) transistors or devices and can have threshold voltages larger than, for example, 5 V.

In some implementations, the semiconductor device 100 further includes one or more low low voltage (LLV) transistors (not shown in FIG. 1). Each of the LLV transistors can include a gate structure and a semiconductor body. The semiconductor body of the LLV transistor can be in contact with the insulating layer 104 and can be aligned with the semiconductor body 108b of the transistor 108 along a horizontal direction (e.g., the X direction or the Y direction). The gate structure of the LLV transistor can include a dielectric layer. A thickness (e.g., a size along the Z direction) of the dielectric layer of the LLV transistor is smaller than the thickness of the dielectric layer 108a-2 of the transistor 108. The LLV transistor operates in a lower voltage range than the transistor 108. For example, the LLV transistor can have a threshold voltage smaller than or equal to 1.6 V.

FIG. 2 illustrates a side view of an example semiconductor device 200. In some implementations, gate structures of some transistors (e.g., transistor 212 of FIG. 2) of the semiconductor device 200 differs from gate structures of some transistors (e.g., transistor 112 of FIG. 1) of the semiconductor device 100. The semiconductor device 200 includes a semiconductor layer 202 (also referred to as substrate), an insulating layer 204, and a semiconductor layer 206 (also referred to as substrate). The insulating layer 204 and the semiconductor layer 206 are stacked on a portion of the semiconductor layer 202 along a vertical direction (e.g., the Z direction). Each of the semiconductor layers 202 and 206 can be any suitable semiconductor substrate having any suitable semiconductor material, such as monocrystalline, polycrystalline, or single crystalline semiconductor. For example, each of the semiconductor layers 202 and 206 can include silicon, SiGe, Ge, GaAs, SOI, GOI, gallium nitride, silicon carbide, III-V compound, or any combinations thereof. The insulating layer 204 can include a dielectric material, such as silicon oxide, silicon nitride, silicon oxynitride, or any combination thereof.

The semiconductor device 200 further includes a transistor 208 and a transistor 212. The transistor 208 can be a FET (e.g., a FDSOI transistor). The FDSOI technique can provide one or more of the following benefits. First, FDSOI can be used to mitigate the leakage issue by achieving an improved I_{ON}/I_{OFF} ratio. Second, compared with traditional silicon structures, FDSOI transistors can achieve faster response times and reduced static power consumption. Third, buried oxide in an SOI can be used as HV gate oxide (HVGOX), thus the FDSOI technique facilitates the integration of HV devices and LV devices in the same semiconductor structure without significant process adjustments. The transistor 208 can include a gate structure 208a and a semiconductor body 208b. The semiconductor body 208b can extend into the semiconductor layer 206 (e.g., along the Z direction). In some implementations, the semiconductor body 208b can be in contact with the insulating layer 204. The gate structure 208a includes a conductive layer 208a-1 and a dielectric layer 208a-2 stacked along the Z direction. The dielectric layer 208a-2 is between the conductive layer 208a-1 and the semiconductor body 208b along the Z direction. The conductive layer 208a-1 includes a conductive material (e.g., polysilicon). The dielectric layer 208a-2 includes a dielectric material (e.g., silicon oxide) and can also be referred to as gate oxide.

The transistor 212 can also be a FET. The transistor 212 includes a gate structure 212a and a semiconductor body 212b. As shown in FIG. 2, the semiconductor body 212b of the transistor 212 can extend into another portion of the semiconductor layer 202 (e.g., along the Z direction). The gate structure 212a includes a conductive layer 212a-1, a dielectric layer 212a-2, and a dielectric layer 212a-3 stacked along the Z direction. In some implementations, the dielectric layer 212a-2 can include a high-K dielectric material, and thus can be referred to as a high-K layer 212a-2. The dielectric layer 212a-3 is between the high-K layer 212a-2 and the semiconductor body 212b along the Z direction. The conductive layer 212a-1 includes a conductive material (e.g., polysilicon). The dielectric layer 212a-3 (also referred to as gate oxide) includes a dielectric material (e.g., silicon oxide). The dielectric layer 212a-3 can be aligned with the insulating layer 204 along a horizontal direction (e.g., the X direction). A size of the dielectric layer 212a-3 of the gate structure 212a along the Z direction can be similar to or same as a size of the insulating layer 204 along the Z direction. In some implementations, a difference between the size of the dielectric layer 212a-3 (e.g., along the Z direction) and the size of the insulating layer 204 (e.g., along the Z direction) is smaller than a threshold. For example, the threshold can be a small percentage (e.g., 10%) of the size (e.g., along the Z direction) of the insulating layer 204. In some implementations, the dielectric layer 212a-2 can include a general type of dielectric material (e.g., silicon oxide). For example, the dielectric layer 212a-2 and the dielectric layer 212a-3 can include the same dielectric material. In some implementations, the gate structure 212a may include the conductive layer 212a-1 and the dielectric layer 212a-3, and may not include the dielectric layer 212a-2 or the high-K layer 212a-2. In other words, the conductive layer 212a-1 can be in contact with the dielectric layer 212a-3 along the Z direction.

The insulating layer 204 can have a surface 204a and a surface 204b. The surface 204a is in contact with the semiconductor body 208b. The surface 204b is in contact with the semiconductor layer 202. The dielectric layer 212a-3 of the gate structure 212a has a surface 220 away from the semiconductor body 212b along the Z direction. The surface 204a of the insulating layer 204 can be aligned with the surface 220 of the dielectric layer 212a-3 along the X direction. The dielectric layer 212a-3 has a surface 222 in contact with the semiconductor body 212b. The surface 204b of the insulating layer 204 can be aligned with the surface 222 of the dielectric layer 212a-3 along the X direction. In some implementations, the insulating layer 204 and the dielectric layer 212a-3 of the gate structure 212a can include the same dielectric material.

The semiconductor body 208b of the transistor 208 can have two terminals 208b-1 and 208b-2. The terminal 208b-1 is on a first side of the semiconductor body 208b, and the terminal 208b-2 is on a second side of the semiconductor body 208b. The first side of the semiconductor body 208b can be opposite to the second side of the semiconductor body 208b along the X direction. One of the terminals 208b-1 and 208b-2 can be a source terminal, and another of the terminals 208b-1 and 208b-2 can be a drain terminal. The semiconductor body 212b of the transistor 212 can have two terminals 212b-1 and 212b-2. The terminal 212b-1 is on a first side of the semiconductor body 212b, and the terminal 212b-2 is on a second side of the semiconductor body 212b. The first side of the semiconductor body 212b can be opposite to the second side of the semiconductor body 212b along the X direction. One of the terminals 212b-1 and 212b-2 can be a source terminal, and another of the terminals 212b-1 and 212b-2 can be a drain terminal.

In some implementations, the semiconductor device 200 further includes a transistor 210 adjacent to the transistor 208. The transistors 208 and 210 can have similar structures. The transistors 208 and 210 can be at different locations in a horizontal plane (e.g., the X-Y plane). In some implementations, source and drain terminals of the transistors 208 and 210 can be doped with suitable dopants, such that one of the transistors 208 and 210 is an n-type FET and another of the transistors 208 and 210 is a p-type FET. In this case, the transistors 208 and 210 can form a CMOS structure 216.

In some implementations, the semiconductor device 200 further includes a transistor 214 adjacent to the transistor 212. The transistors 212 and 214 can have similar structures. The transistors 212 and 214 can be at different locations in a horizontal plane (e.g., the X-Y plane). In some implementations, source and drain terminals of the transistors 212 and 214 can be doped with suitable dopants, such that one of the transistors 212 and 214 is an n-type FET and another of the transistors 212 and 214 is a p-type FET. In this case, the transistors 212 and 214 can form a CMOS structure 218. As shown in FIG. 2, in some implementations, the transistors 208, 210, 212, and 214 can be separated by STIs 228.

In some implementations, a thickness of the dielectric layer 212a-3 of the transistor 212 is larger than a thickness of the dielectric layer 208a-2 of the transistor 208. In other words, a size (e.g., along the Z direction) of the dielectric layer 212a-3 of the transistor 212 is larger than a size (e.g., along the Z direction) of the dielectric layer 208a-2 of the transistor 208. As such, the transistor 212 (as well as the transistor 214 and the CMOS structure 218) can operate in a higher voltage range than the transistor 208 (as well as the transistor 210 and the CMOS structure 216). In some implementations, the transistor 208, the transistor 210, and the CMOS structure 216 can be referred to as LV transistors or devices and can have threshold voltages smaller than or equal to, for example, 5 V. The transistor 212, the transistor 214, and the CMOS structure 218 can be referred to as HV transistors or devices and can have threshold voltages larger than, for example, 5 V.

In some implementations, the semiconductor device 200 further includes one or more LLV transistors (not shown in FIG. 2). Each of the LLV transistors can include a gate structure and a semiconductor body. The semiconductor body of the LLV transistor can be in contact with the insulating layer 204 and can be aligned with the semiconductor body 208b of the transistor 208 along a horizontal direction (e.g., the X direction or the Y direction). The gate structure of the LLV transistor can include a dielectric layer. A thickness (e.g., a size along the Z direction) of the dielectric layer of the LLV transistor is smaller than the thickness of the dielectric layer 208a-2 of the transistor 208. The LLV transistor operates in a lower voltage range than the transistor 208. For example, the LLV transistor can have a threshold voltage smaller than or equal to 1.6 V.

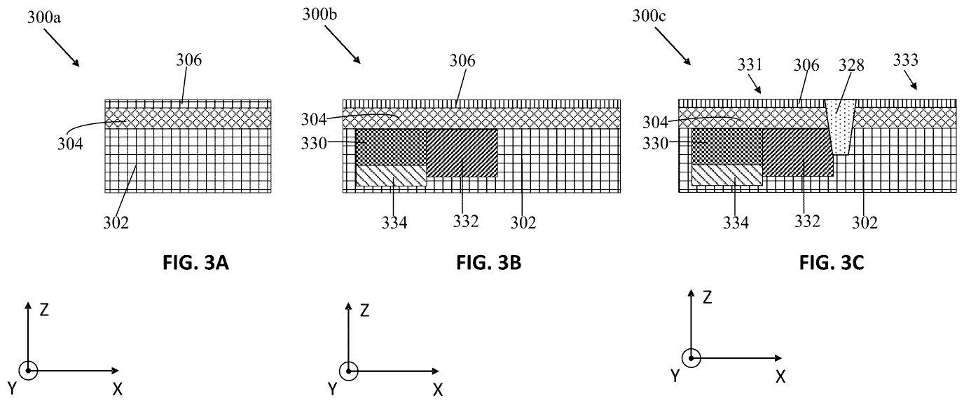

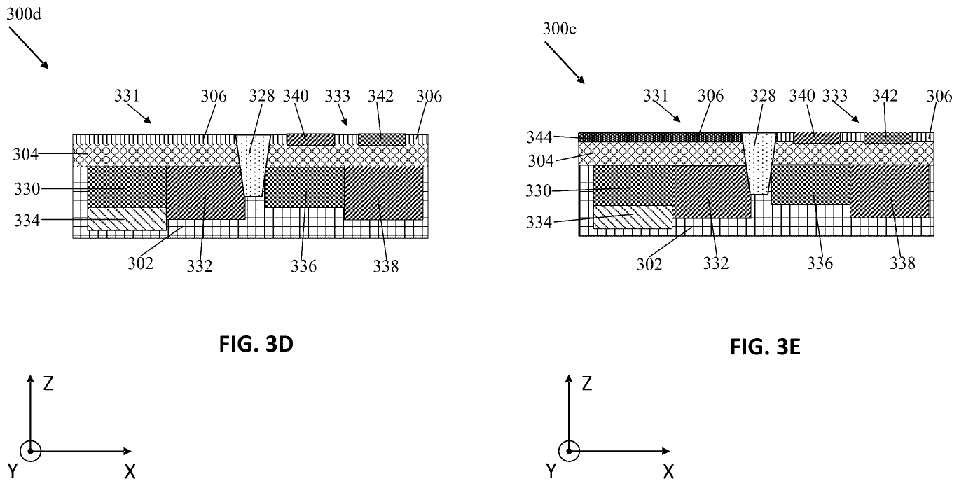

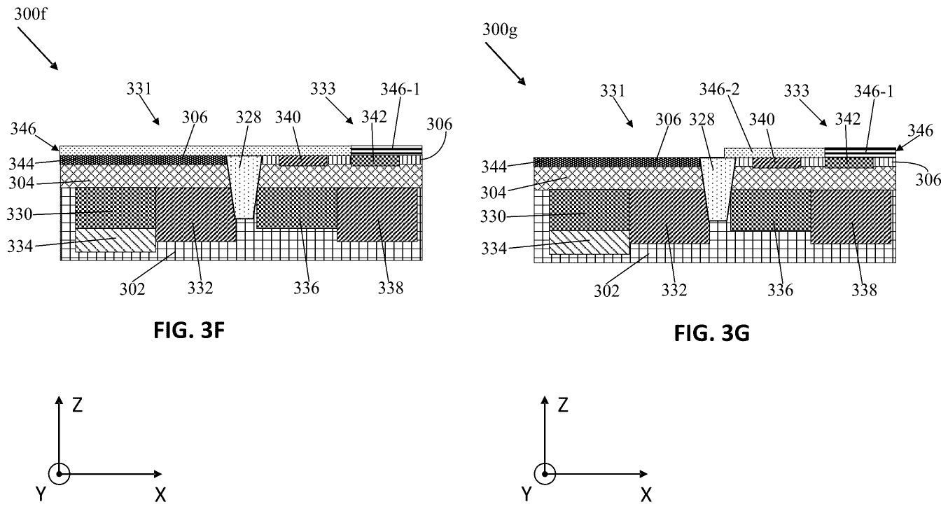

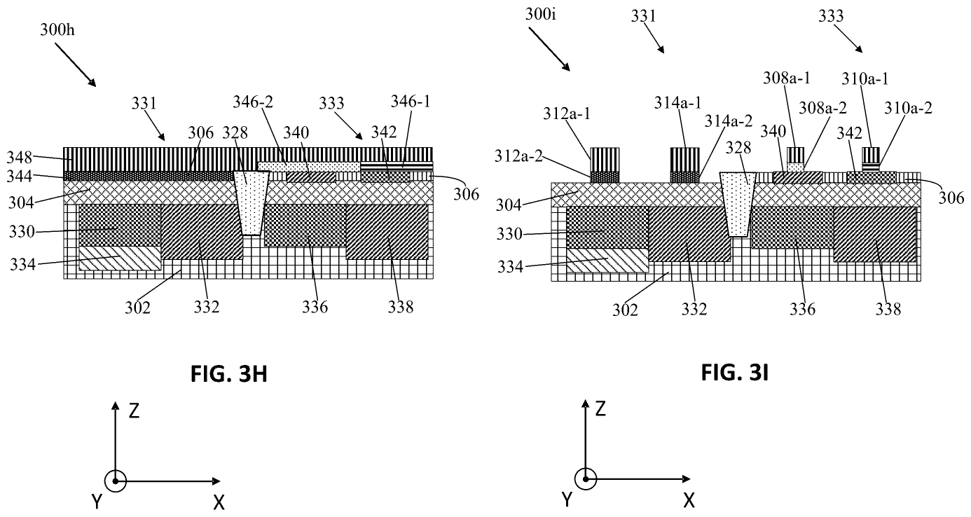

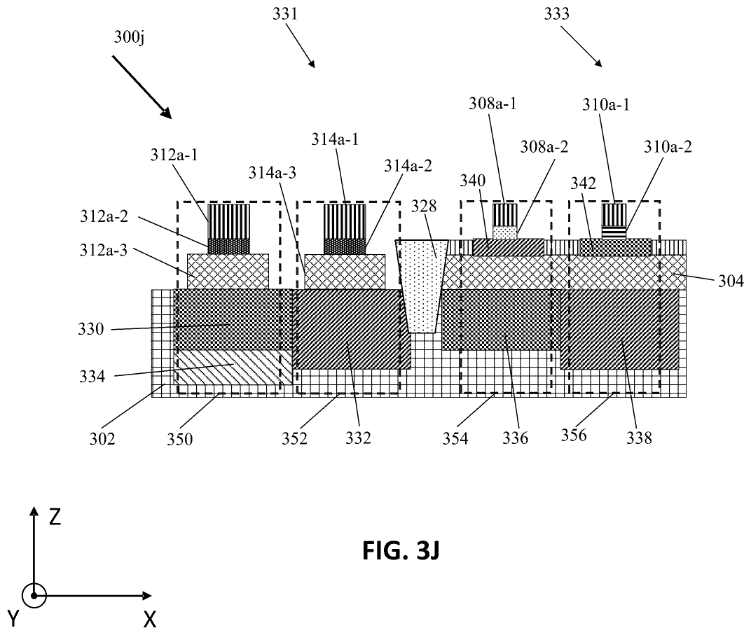

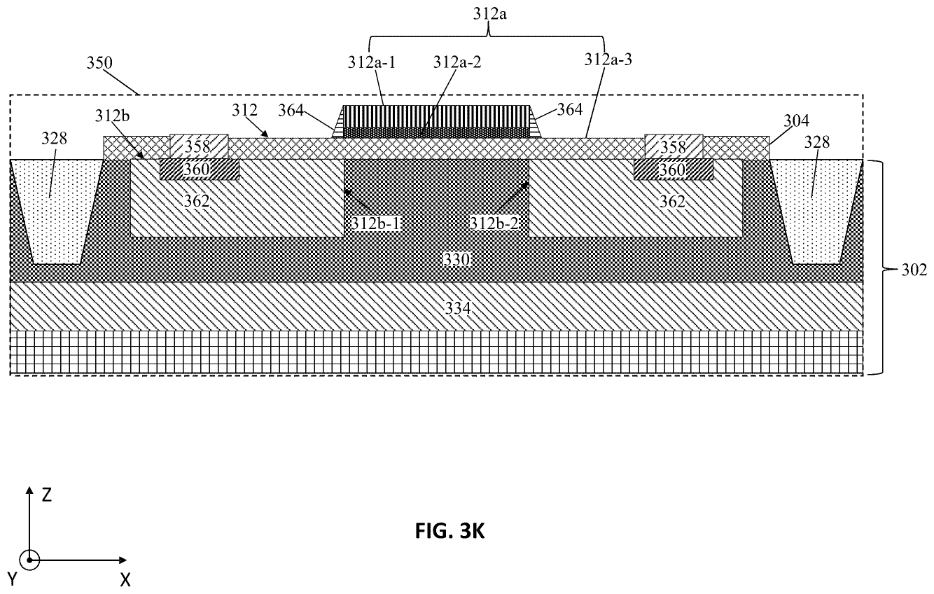

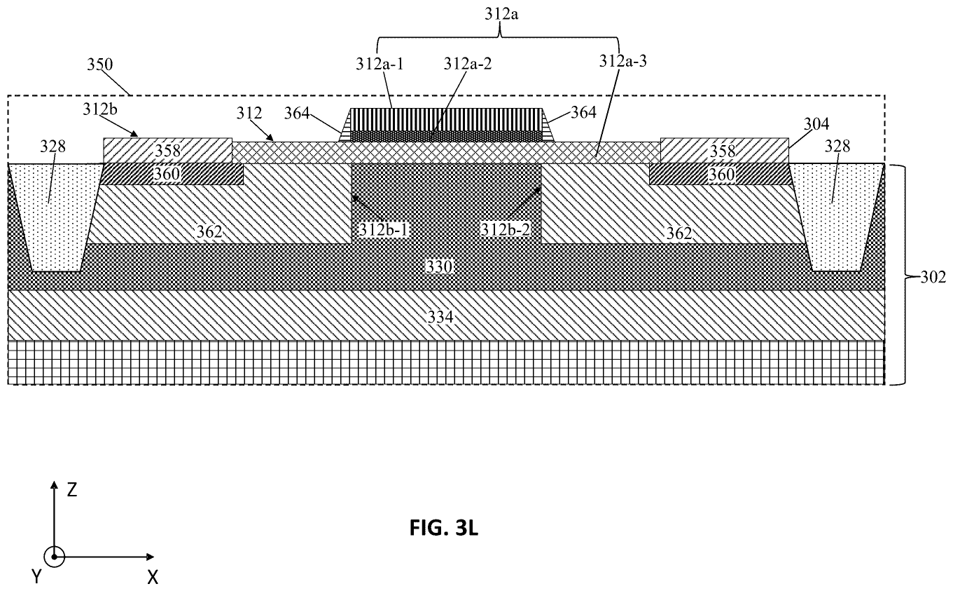

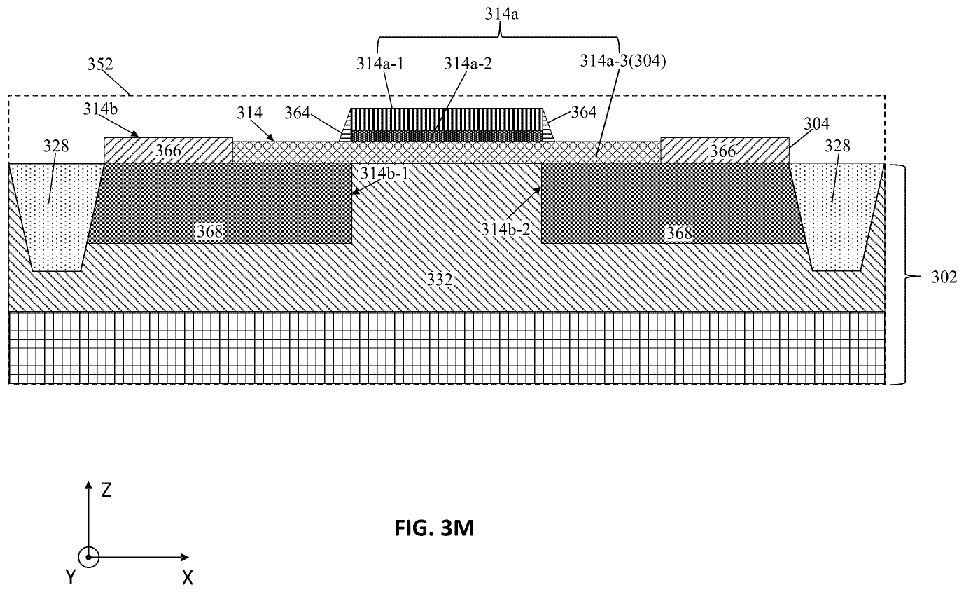

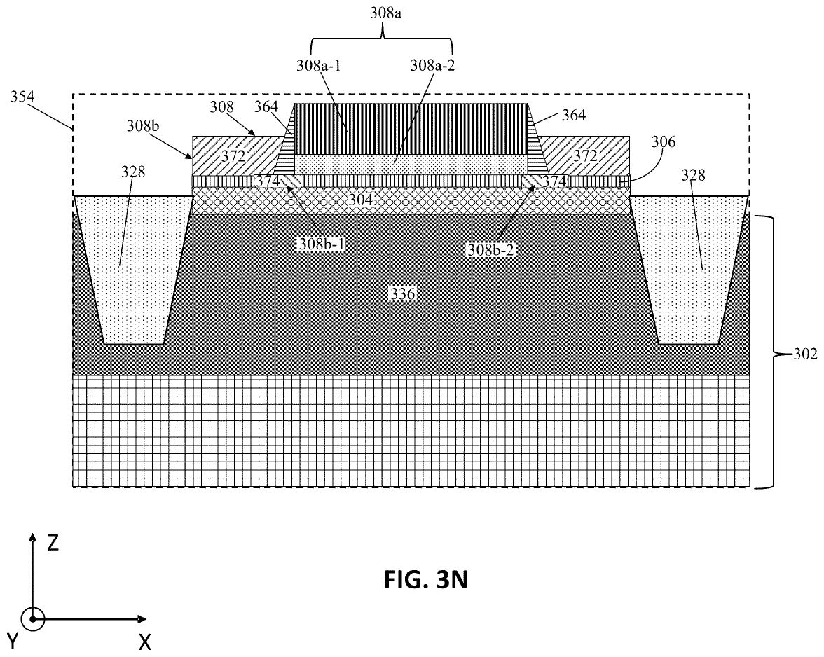

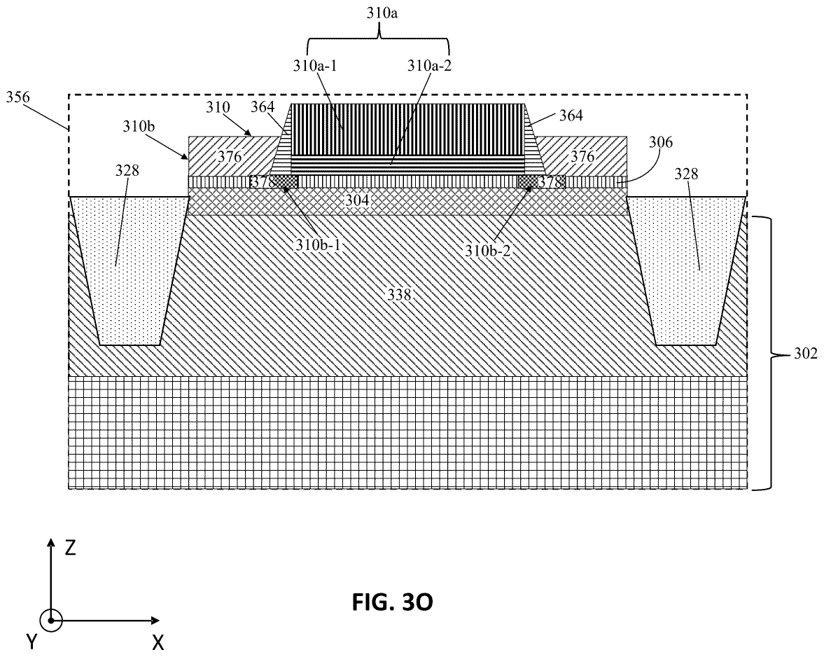

FIGS. 3A-3O illustrate an example process of fabricating a semiconductor device, such as the semiconductor device 100 as illustrated in FIG. 1. FIGS. 3A-3O show side views of example semiconductor structures at various stages of the fabrication process.

As shown in FIG. 3A, a semiconductor structure 300a including a semiconductor layer 302 (also referred to as substrate), an insulating layer 304, and a semiconductor layer 306 (also referred to as substrate) is formed. The semiconductor layer 302, the insulating layer 304, and the semiconductor layer 306 can be stacked along the Z direction. The semiconductor structure 300a can be formed, for example, by stacking the insulating layer 304 on the semiconductor layer 302 and stacking the semiconductor layer 306 on the insulating layer 304. Each of the semiconductor layers 302 and 306 can be any suitable semiconductor substrate having any suitable semiconductor material, such as monocrystalline, polycrystalline, or single crystalline semiconductor. For example, each of the semiconductor layers 302 and 306 can include silicon, SiGe, Ge, GaAs, SOI, GOI, gallium nitride, silicon carbide, III-V compound, or any combinations thereof. The insulating layer 304 can include a dielectric material, such as silicon oxide, silicon nitride, silicon oxynitride, or any combination thereof. In some implementations, the semiconductor layer 306 can be thinner than the semiconductor layer 302. That is, a size of the semiconductor layer 306 along the Z direction is smaller than a size of the semiconductor layer 302 along the Z direction. The process of forming the semiconductor structure 300a can be called Silicon-On-Insulator (SOI) technology as the semiconductor layer 306 is placed on top of the insulating layer 304.

As shown in FIG. 3B, a semiconductor structure 300b is formed by heavily doping the semiconductor layer 306 using a dopant (e.g., an N-type dopant). The semiconductor layer 302 of the semiconductor structure 300b includes a P-type well 330 and an N-type well 332. In some implementations, the P-type well 330 and the N-type well 332 can be used in a high voltage environment, and thus can be referred to as a high voltage P-type well and a high voltage N-type well, respectively. The semiconductor layer 302 of the semiconductor structure 300b can further include a deep N-type well 334 implanted deeper (e.g., along the Z direction) than the P-type well 330. It is understood that any suitable doping method can be used to form doped regions (e.g., the P-type well 330, the N-type well 332, the deep N-type well 334, and doped regions in other figures of the present disclosure) in the fabrication process. As shown in FIG. 3B, the P-type well 330 and the N-type well 332 can be adjacent to each other along the X direction, and the P-type well 330 and the deep N-type well 334 can be adjacent to each other along the Z direction.

FIG. 3C illustrates a semiconductor structure 300c, which includes an isolation structure 328. The isolation structure 328 can be formed, for example, using STI (Shallow Trench Isolation) techniques. The isolation structure 328 can be adjacent to the N-type well 332 along the X direction. In some implementations, the isolation structure 328 can extend through the semiconductor layer 306 (e.g., heavily doped) and the insulating layer 304, and can extend into the semiconductor layer 302. The isolation structure 328 can divide the semiconductor structure 300c into a high voltage region 331 and a low voltage region 333 arranged along the X direction. The isolation structure 328 can be used to electrically isolate individual transistors (e.g., transistors 312 and 314 of FIGS. 3K-3M) in the high voltage region 331 from individual transistors in the low voltage region 333 (e.g., transistors 308 and 310 of FIGS. 3M-3O). In some implementations (e.g., as shown in FIGS. 3K-3O), the isolation structure 328 can be used to electrically isolate a transistor (e.g., in the high voltage region 331 or the low voltage region 333) from another adjacent transistor in the same region. The P-type well 330, the N-type well 332, and deep N-type well 334 are in the high voltage region 331.

FIG. 3D illustrates a semiconductor structure 300d, which includes a P-type well 336, an N-type well 338, an N-type region 340, and a P-type region 342 in the low voltage region 333. The P-type well 336 and the N-type well 338 can be formed (e.g., by doping) in the semiconductor layer 302 and can be arranged adjacent to each other along the X direction. It is understood that the above doped regions and doping types are for illustration purpose and are not intended to be construed in a limiting sense. In practice, the semiconductor structure 300d may have different structures from those shown in FIG. 3D, and any suitable doping process can be applied to the fabrication process. In some implementations, the P-type well 336 and the N-type well 338 can be used in a low voltage environment, and thus can be referred to as a low voltage P-type well and a low voltage N-type well, respectively. The N-type region 340 can be formed in the semiconductor layer 306 over the P-type well 336 along the Z direction. The P-type region 342 can be formed in the semiconductor layer 306 over the N-type well 338 along the Z direction. The N-type region 340 can be formed by doping a portion of the semiconductor layer 306, and the P-type region 342 can be formed by doping another portion of the semiconductor layer 306. Both the N-type region 340 and the P-type region 342 can be in contact with the insulating layer 304.

In some implementations, the N-type region 340 can be used to form a semiconductor body of a transistor (e.g., the transistor 308 of FIG. 3N) in a later process. The N-type region 340 can be doped using an appropriate amount of N-type dopant depending on a threshold voltage requirement of the transistor. Similarly, the P-type region 342 can be doped using an appropriate amount of P-type dopant depending on a threshold voltage requirement of a transistor (e.g., the transistor 310 of FIG. 3O), whose semiconductor body is formed by the P-type region 342 later.

As shown in FIG. 3D, the isolation structure 328 can separate the P-type well 330, the N-type well 332, and the deep N-type well 334 in the high voltage region 331 from the P-type well 336, the N-type well 338, the N-type region 340, and the P-type region 342 in the low voltage region 333 (e.g., along the X direction).

FIG. 3E illustrates a semiconductor structure 300e, which can be formed by doping a region 344 of the semiconductor layer 306 using an N-type dopant. The region 344 can be located in the high voltage region 331 over the P-type well 330, the N-type well 332, and the deep N-type well 334 (e.g., along the Z direction). The isolation structure 328 can separate the region 344 from the N-type region 340 and the P-type region 342 (e.g., along the X direction).

FIG. 3F illustrates a semiconductor structure 300f, which includes a high-K dielectric layer 346 deposited on top of the semiconductor layer 306 (e.g., along the Z direction). Alternatively, in some implementations, an insulating layer that includes a general type of dielectric material (e.g., silicon oxide) can be deposited on top of the semiconductor layer 306. The high-K dielectric layer 346 can include a portion 346-1 in the low voltage region 333. The portion 346-1 is on top of and in contact with the P-type region 342. The portion 346-1 can be doped with a P-type dopant. The remaining portion of the high-K dielectric layer 346 can be doped with an N-type dopant.

As shown in FIG. 3G, a semiconductor structure 300g can be formed by removing (e.g., by etching) a portion of the high-K dielectric layer 346 in the high voltage region 331 to expose the region 344 of the semiconductor layer 306. Now the high-K dielectric layer 346 includes a portion 346-2 (e.g., N-type) and the portion 346-1 (e.g., P-type) both located in the low voltage region 333.

FIG. 3H illustrates a semiconductor structure 300h, which includes a polysilicon layer 348 deposited on top of the semiconductor structure 300g. That is, the polysilicon layer 348 is stacked over the insulating layer 304 and is in contact with the region 344 of the semiconductor layer 306 in the high voltage region 331 and the high-K dielectric layer 346 in the low voltage region 333.

FIG. 3I illustrates a semiconductor structure 300i, which can be formed by partially removing (e.g., by etching) the polysilicon layer 348, the region 344 of the semiconductor layer 306, and the high-K dielectric layer 346. In some implementations, the polysilicon layer 348 can be conductive (e.g., by doping it with an N-type dopant or a P-type dopant). As shown in FIG. 3I, a remaining portion of the polysilicon layer 348 includes a conductive layer 312a-1, a conductive layer 314a-1, a conductive layer 308a-1, and a conductive layer 310a-1. The conductive layer 312a-1 and the conductive layer 314a-1 are in the high voltage region 331. The conductive layer 308a-1 and the conductive layer 310a-1 are in the low voltage region 333. A remaining portion of the semiconductor layer 306 can include a semiconductive layer 312a-2 and a semiconductive layer 314a-2. A remaining portion of the high-K dielectric layer 346 includes a dielectric layer 308a-2 (e.g., N-type) and a dielectric layer 310a-2 (e.g., P-type). The conductive layer 312a-1 is in contact with the semiconductive layer 312a-2 along the Z direction. The conductive layer 314a-1 is in contact with the semiconductive layer 314a-2 along the Z direction. The conductive layer 308a-1 is in contact with the dielectric layer 308a-2 along the Z direction. The conductive layer 310a-1 is in contact with the dielectric layer 310a-2 along the Z direction.

FIG. 3J illustrates a semiconductor structure 300j, which can be formed by partially removing the insulating layer 304 in the high voltage region 331. A remaining portion of the insulating layer 304 in the high voltage region 331 can include a dielectric layer 312a-3 and a dielectric layer 314a-3 separate from each other (e.g., along the X direction). The dielectric layer 312a-3 is between and in contact with the semiconductor layer 312a-2 and the P-type well 330 along the Z direction. The dielectric layer 314a-3 is between and in contact with the semiconductor layer 314a-2 and the N-type well 332 along the Z direction. The conductive layer 312a-1, the semiconductor layer 312a-2, and the dielectric layer 312a-3 can form a gate structure 312a of a transistor formed later (e.g., the transistor 312 of FIG. 3K or 3L). The conductive layer 314a-1, the semiconductor layer 314a-2, and the dielectric layer 314a-3 can form a gate structure 314a of a transistor formed later (e.g., the transistor 314 of FIG. 3M). The conductive layer 308a-1 and the dielectric layer 308a-2 can form a gate structure 308a of a transistor formed later (e.g., the transistor 308 of FIG. 3N). The conductive layer 310a-1 and the dielectric layer 310a-2 can form a gate structure 310a of a transistor formed later (e.g., the transistor 310 of FIG. 3O).

FIGS. 3K-3O illustrate transistors that can be formed from the semiconductor structure 300j of FIG. 3J. For example, FIG. 3K illustrates an implementation of an N-type transistor 312 formed using the gate structure 312a. FIG. 3L illustrates another implementation of the N-type transistor 312 formed using the gate structure 312a. FIG. 3M illustrates an implementation of a P-type transistor 314 formed using the gate structure 314a. FIG. 3N illustrates an implementation of an N-type transistor 308 formed using the gate structure 308a. FIG. 3O illustrates an implementation of a P-type transistor 310 formed using the gate structure 310a. It is understood that the structures shown in FIGS. 3K-3O are for illustration purpose and are not intended to be construed in a limiting sense. In practice, the transistors 308, 310, 312, and 314 may have different structures from those shown in FIGS. 3K-3O, and any suitable fabrication process can be applied to the forming process of these transistors.

FIG. 3K illustrates an implementation of the N-type transistor 312 in an enlarged view of an area 350 of FIG. 3J. As shown in FIG. 3K, the N-type transistor 312 can be formed from the semiconductor structure 300j. For example, the N-type transistor 312 can include the gate structure 312a and a semiconductor body 312b. The semiconductor body 312b extends into the P-type well 330 along the Z direction and is in contact with the dielectric layer 312a-3. The semiconductor body 312b can have two terminals 312b-1 and 312b-2. The terminal 312b-1 is on a first side of the semiconductor body 312b, and the terminal 312b-2 is on a second side of the semiconductor body 312b. The first side of the semiconductor body 312b can be opposite to the second side of the semiconductor body 312b along the X direction. One of the terminals 312b-1 and 312b-2 can be a source terminal, and another of the terminals 312b-1 and 312b-2 can be a drain terminal. Each of the terminals 312b-1 and 312b-2 can include an N-type epitaxial layer 358, an N-type lightly doped structure 360, and an N-type lightly doped structure 362. The N-type epitaxial layers 358 can be formed in the insulating layer 304. Each N-type epitaxial layer 358 is in contact with a respective N-type lightly doped structure 360 along the Z direction. The N-type lightly doped structure 360 is in the N-type lightly doped structure 362, and the N-type lightly doped structure 362 is in the P-type well 330. The N-type lightly doped structure 360 and the N-type lightly doped structure 362 can be formed by any suitable doping methods, such as ion implantation. The N-type lightly doped structure 360 and the N-type lightly doped structure 362 can be referred to as lightly doped drains if they are part of a drain terminal and can be referred to as lightly doped sources if they are part of a source terminal. In some implementations, the gate structure 312a can be between dielectric spacers 364 (e.g., along the X direction). The N-type transistor 312 can be between two isolation structures 328 along the X direction. The two isolation structures 328 can separate the N-type transistor 312 from another transistor adjacent to the N-type transistor 312. The N-type transistor 312 of FIG. 3K is an implementation of the transistor 112 of FIG. 1. In some implementations, the N-type transistor 312 of FIG. 3K can be an HV transistor.

FIG. 3L illustrates another implementation of the N-type transistor 312 in the enlarged view of the area 350 of FIG. 3J. The N-type transistor 312 in FIG. 3L is similar to the N-type transistor 312 in FIG. 3K. As shown in FIG. 3L, the N-type transistor 312 can be formed from the semiconductor structure 300j. For example, the N-type transistor 312 can include the gate structure 312a and a semiconductor body 312b. The semiconductor body 312b extends into the P-type well 330 along the Z direction and is in contact with the dielectric layer 312a-3. The semiconductor body 312b can have two terminals 312b-1 and 312b-2. The terminal 312b-1 is on a first side of the semiconductor body 312b, and the terminal 312b-2 is on a second side of the semiconductor body 312b. The first side of the semiconductor body 312b can be opposite to the second side of the semiconductor body 312b along the X direction. One of the terminals 312b-1 and 312b-2 can be a source terminal, and another of the terminals 312b-1 and 312b-2 can be a drain terminal. Each of the terminals 312b-1 and 312b-2 can include an N-type epitaxial layer 358, an N-type lightly doped structure 360, and an N-type lightly doped structure 362. The N-type epitaxial layers 358 can be formed in the insulating layer 304. Each N-type epitaxial layer 358 is in contact with a respective N-type lightly doped structure 360 along the Z direction. The N-type lightly doped structure 360 is in the N-type lightly doped structure 362, and the N-type lightly doped structure 362 is in the P-type well 330. The N-type lightly doped structure 360 and the N-type lightly doped structure 362 can be formed by any suitable doping methods, such as ion implantation. The N-type lightly doped structure 360 and the N-type lightly doped structure 362 can be referred to as lightly doped drains if they are part of a drain terminal and can be referred to as lightly doped sources if they are part of a source terminal. In some implementations, the gate structure 312a can be between dielectric spacers 364 (e.g., along the X direction). The N-type transistor 312 can be between two isolation structures 328 along the X direction. The two isolation structures 328 can separate the N-type transistor 312 from another transistor adjacent to the N-type transistor 312. The N-type transistor 312 of FIG. 3L is another implementation of the transistor 112 of FIG. 1. In some implementations, the N-type transistor 312 of FIG. 3L can be an HV transistor.

In practice, the structures of the terminals 312b-1 and 312b-2 may vary in different implementations. In the example of FIG. 3K, a portion of the P-type well 330 can separate each of the terminals 312b-1 and 312b-2 from the adjacent isolation structure 328 (e.g., along the X direction). In addition, in the example of FIG. 3K, each N-type epitaxial layer 358 can be surrounded by the insulating layer 304 (e.g., the dielectric layer 312a-3). In the example of FIG. 3L, each of the terminals 312b-1 and 312b-2 (e.g., the N-type lightly doped structures 360 and 362) can be in contact with the adjacent isolation structure 328 (e.g., along the X direction). In addition, in the example of FIG. 3L, the insulating layer 304 (e.g., the dielectric layer 312a-3) can be between the two N-type epitaxial layers 358 (e.g., along the X direction).

FIG. 3M illustrates an implementation of the P-type transistor 314 in an enlarged view of an area 352 of FIG. 3J. As shown in FIG. 3M, the P-type transistor 314 can be formed from the semiconductor structure 300j. For example, the P-type transistor 314 can include the gate structure 314a and a semiconductor body 314b. The semiconductor body 314b extends into the N-type well 332 along the Z direction and is in contact with the dielectric layer 314a-3 (e.g., a portion of the insulating layer 304). The semiconductor body 314b can have two terminals 314b-1 and 314b-2. The terminal 314b-1 is on a first side of the semiconductor body 314b, and the terminal 314b-2 is on a second side of the semiconductor body 314b. The first side of the semiconductor body 314b can be opposite to the second side of the semiconductor body 314b along the X direction. One of the terminals 314b-1 and 314b-2 can be a source terminal, and another of the terminals 314b-1 and 314b-2 can be a drain terminal. Each of the terminals 314b-1 and 314b-2 can include a P-type epitaxial layer 366 and a P-type lightly doped structure 368. The P-type epitaxial layer 366 is in contact with the P-type lightly doped structure 368 along the Z direction. The P-type lightly doped structure 368 is in the N-type well 332. The P-type lightly doped structure 368 can be formed by any suitable doping methods, such as ion implantation. The P-type lightly doped structure 368 can be referred to as a lightly doped drain if it is part of a drain terminal and can be referred to as a lightly doped source if it is part of a source terminal. In some implementations, the gate structure 314a can be between dielectric spacers 364. The P-type transistor 314 can be between two isolation structures 328 along the X direction. The two isolation structures 328 can separate the P-type transistor 314 from another transistor adjacent to the P-type transistor 314. The P-type transistor 314 of FIG. 3M is an implementation of the transistor 114 of FIG. 1. In some implementations, the P-type transistor 314 of FIG. 3M can be an HV transistor.

FIG. 3N illustrates an implementation of the N-type transistor 308 in an enlarged view of an area 354 of FIG. 3J. As shown in FIG. 3N, the N-type transistor 308 can be formed from the semiconductor structure 300j. For example, the N-type transistor 308 can include the gate structure 308a and a semiconductor body 308b. The semiconductor body 308b is in contact with the insulating layer 304. The semiconductor body 308b can have two terminals 308b-1 and 308b-2. The terminal 308b-1 is on a first side of the semiconductor body 308b, and the terminal 308b-2 is on a second side of the semiconductor body 308b. The first side of the semiconductor body 308b can be opposite to the second side of the semiconductor body 308b along the X direction. One of the terminals 308b-1 and 308b-2 can be a source terminal, and another of the terminals 308b-1 and 308b-2 can be a drain terminal. Each of the terminals 308b-1 and 308b-2 can include an N-type epitaxial layer 372 and an N-type lightly doped structure 374. The N-type epitaxial layer 372 is in contact with the N-type lightly doped structure 374 along the Z direction. Each N-type lightly doped structure 374 is in the semiconductor layer 306. The N-type lightly doped structure 374 can be formed by any suitable doping methods, such as ion implantation. The N-type lightly doped structure 374 can be referred to as a lightly doped drain if it is part of a drain terminal and can be referred to as a lightly doped source if it is part of a source terminal. In some implementations, the gate structure 308a can be isolated from the N-type epitaxial layer 372 by dielectric spacers 364 (e.g., along the X direction). The N-type transistor 308 can be between two isolation structures 328 along the X direction. The two isolation structures 328 can separate the N-type transistor 308 from another transistor adjacent to the N-type transistor 308. The N-type transistor 308 of FIG. 3N is an implementation of the transistor 108 of FIG. 1. In some implementations, the N-type transistor 308 of FIG. 3N can be an LV transistor.

FIG. 3O illustrates an implementation of the P-type transistor 310 in an enlarged view of an area 356 of FIG. 3J. As shown in FIG. 3O, the P-type transistor 310 can be formed from the semiconductor structure 300j. For example, the P-type transistor 310 can include the gate structure 310a and a semiconductor body 310b. The semiconductor body 310b is in contact with the insulating layer 304. The semiconductor body 310b can have two terminals 310b-1 and 310b-2. The terminal 310b-1 is on a first side of the semiconductor body 310b, and the terminal 310b-2 is on a second side of the semiconductor body 310b. The first side of the semiconductor body 310b can be opposite to the second side of the semiconductor body 310b along the X direction. One of the terminals 310b-1 and 310b-2 can be a source terminal, and another of the terminals 310b-1 and 310b-2 can be a drain terminal. Each of the terminals 310b-1 and 310b-2 can include a P-type epitaxial layer 376 and a P-type lightly doped structure 378. The P-type epitaxial layer 376 is in contact with the P-type lightly doped structure 378 along the Z direction. Each P-type lightly doped structure 378 is in the semiconductor layer 306. The P-type lightly doped structure 378 can be formed by any suitable doping methods, such as ion implantation. The P-type lightly doped structure 378 can be referred to as a lightly doped drain if it is part of a drain terminal and can be referred to as a lightly doped source if it is part of a source terminal. In some implementations, the gate structure 310a can be isolated from the P-type epitaxial layer 376 by dielectric spacers 364 (e.g., along the X direction). The P-type transistor 310 can be between two isolation structures 328 along the X direction. The two isolation structures 328 can separate the P-type transistor 310 from another transistor adjacent to the P-type transistor 310. The P-type transistor 310 of FIG. 3O is an implementation of the transistor 110 of FIG. 1. In some implementations, the P-type transistor 310 of FIG. 3O can be an LV transistor.

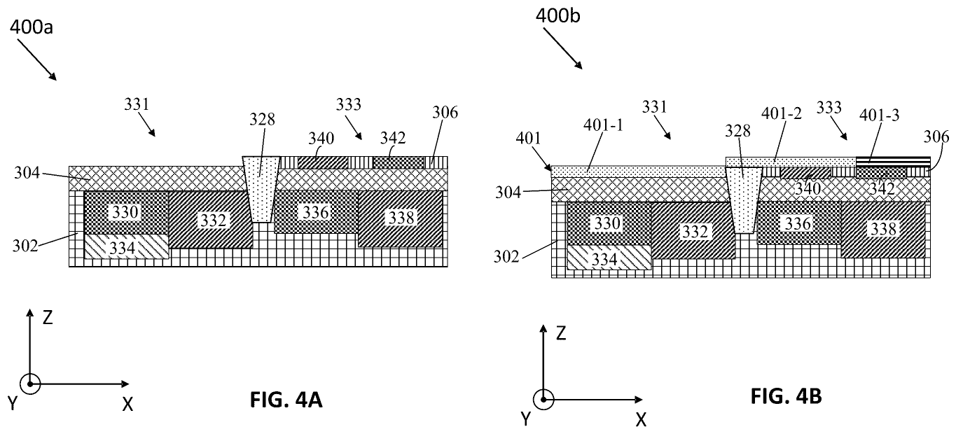

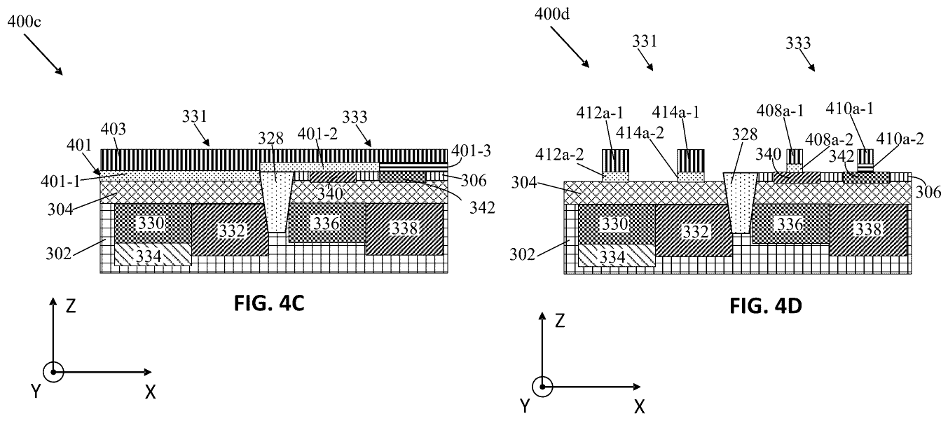

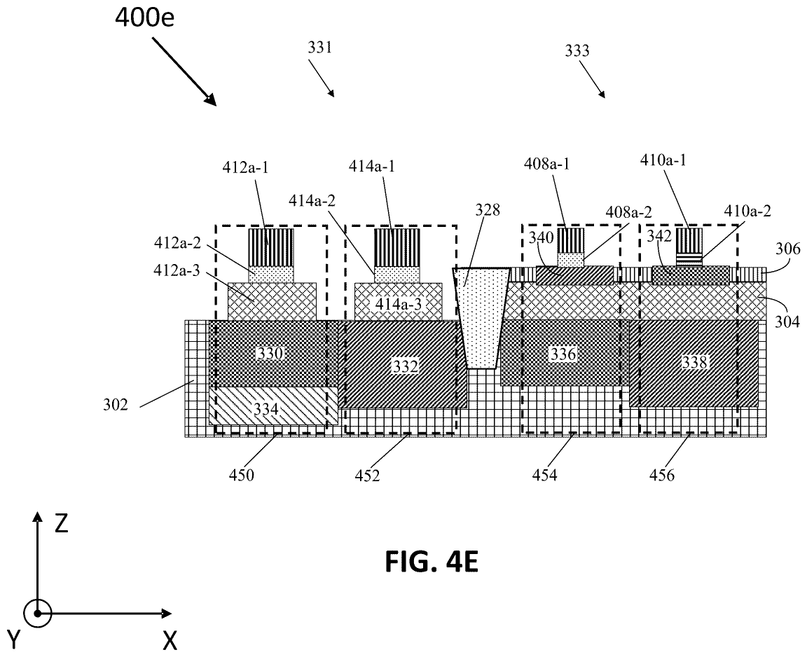

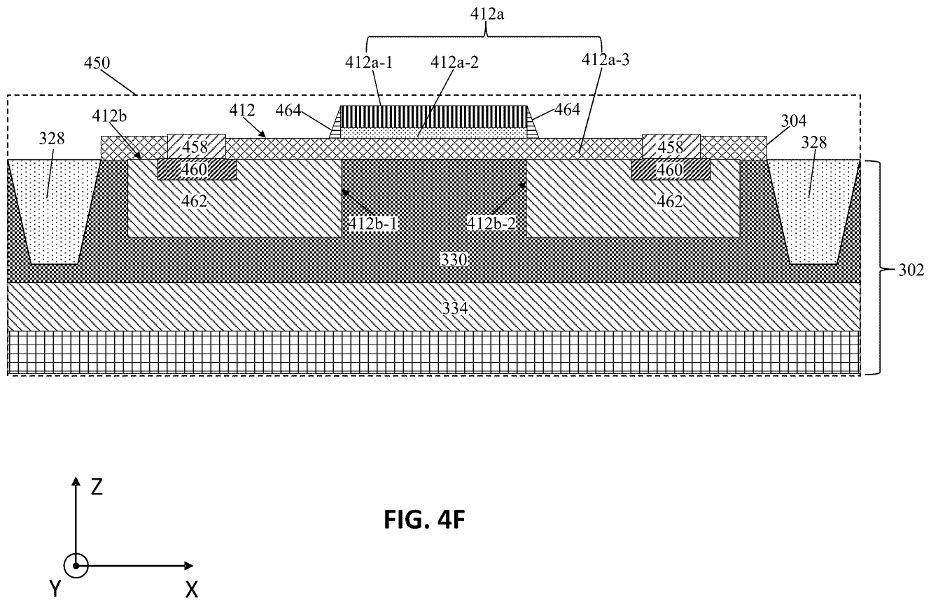

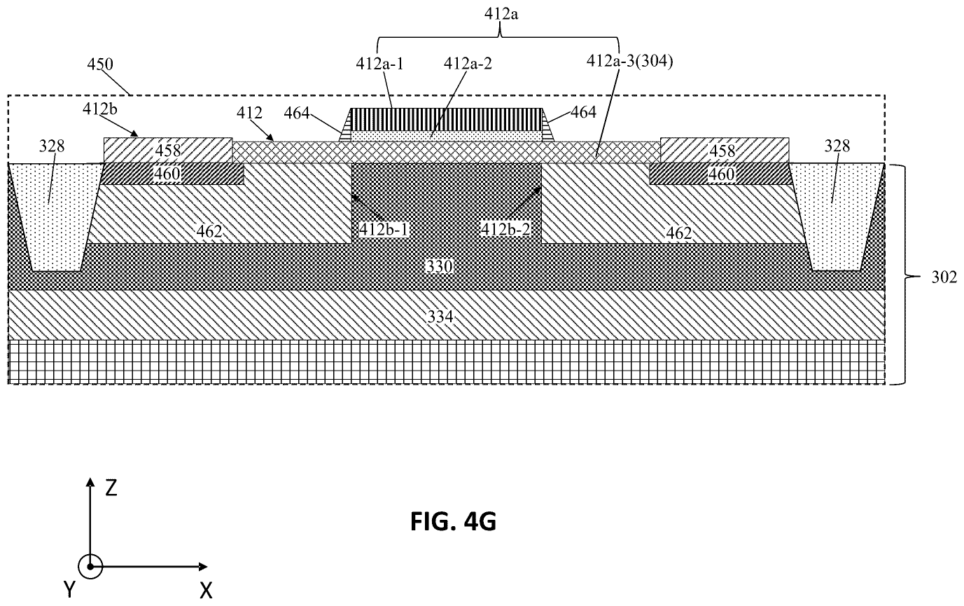

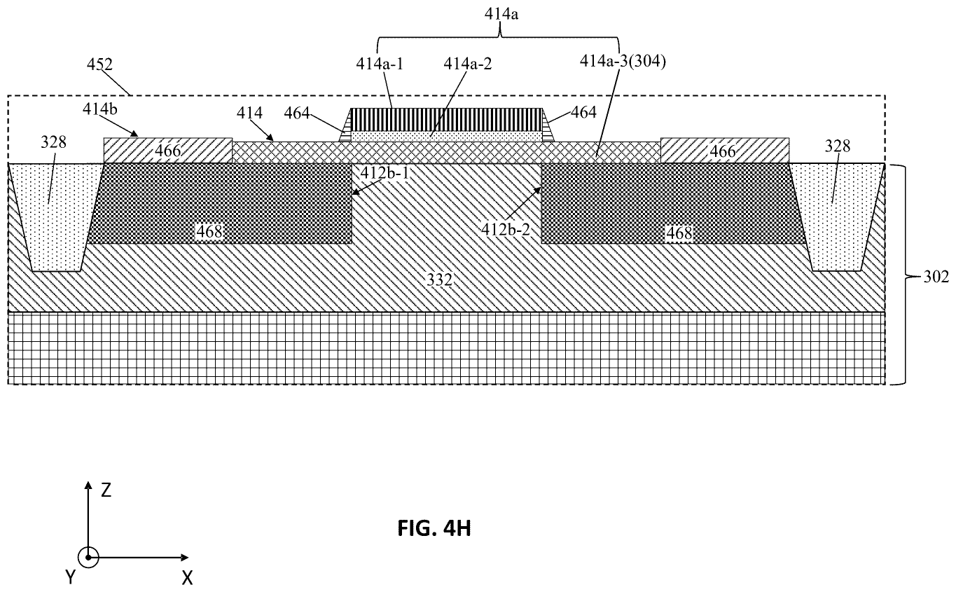

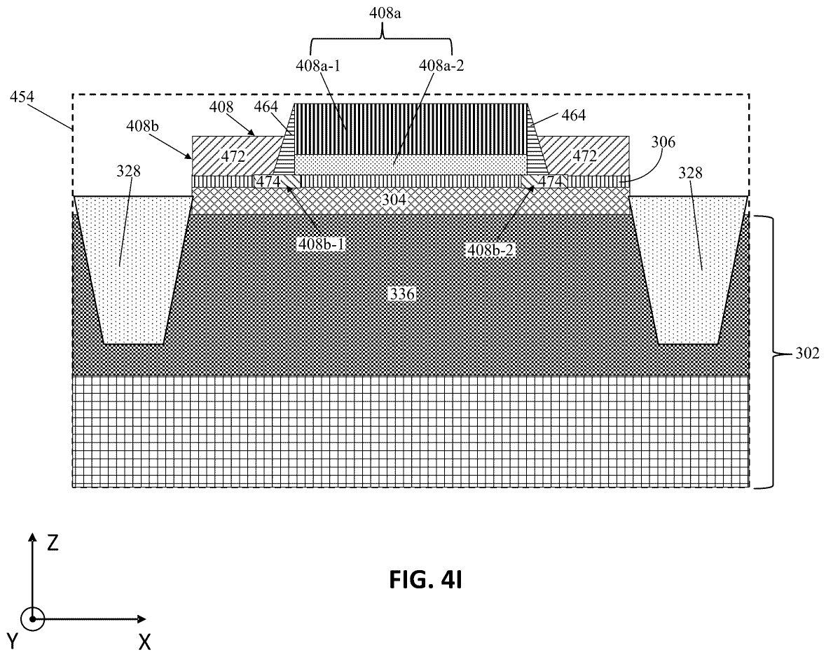

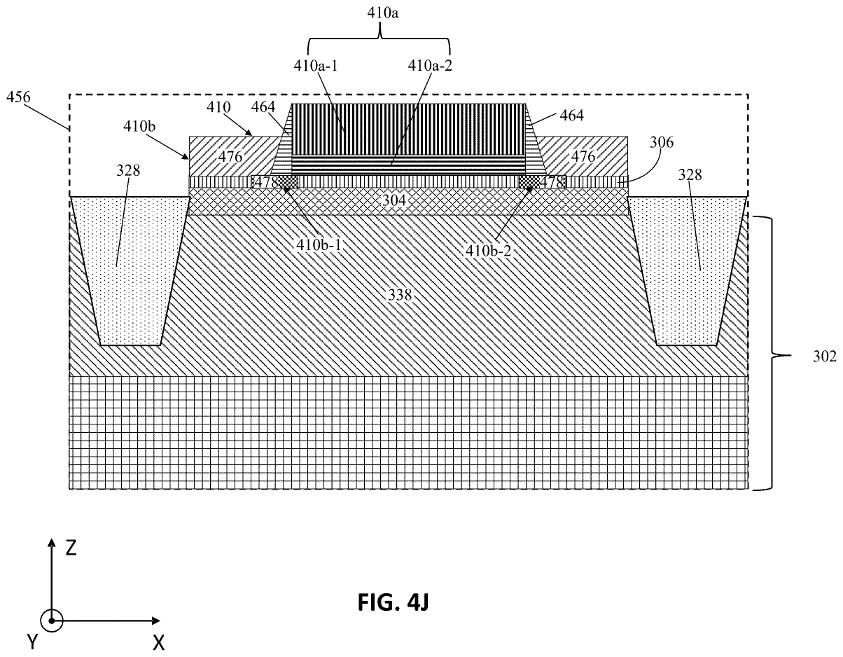

FIGS. 4A-4J illustrate an example process of fabricating a semiconductor device, such as the semiconductor device 200 as illustrated in FIG. 2. FIGS. 4A-4J show side views of example semiconductor structures at various stages of the fabrication process.

FIG. 4A illustrates a semiconductor structure 400a. The semiconductor structure 400a can be formed from the semiconductor structure 300d of FIG. 3D. For example, the semiconductor structure 400a can be formed by removing a portion of the semiconductor layer 306 in the high voltage region 331. As shown in FIG. 4A, the insulating layer 304 of the semiconductor structure 400a is exposed in the high voltage region 331.

FIG. 4B illustrates a semiconductor structure 400b, which can be formed by depositing a high-K dielectric layer 401 on top of the semiconductor structure 400a. The high-K dielectric layer 401 can include a portion 401-1 in the high voltage region 331 and portions 401-2 and 401-3 in the low voltage region 333. The portion 401-1 is on top of and in contact with the insulating layer 304 in the high voltage region 331. The portion 401-2 is on top of and in contact with the N-type region 340. The portion 401-3 is on top of and in contact with the P-type region 342. The portions 401-2 and 401-3 can be adjacent to each other along the X direction. In some implementations, the portion 401-1 and the portion 401-2 can be doped with an N-type dopant, and the portion 401-3 can be doped with a P-type dopant. In some implementations, the portions 401-2 and 401-3 can be located at the same position along the Z direction, and the portions 401-1 and 401-2 can be located at different positions along the Z direction. It is understood that the example of FIG. 4B is for illustration purpose and is not intended to be construed in a limiting sense. In practice, the high-K dielectric layer 401 may not be necessary. For example, a general type of dielectric layer (e.g., silicon oxide), rather than the high-K dielectric layer 401, can be deposited on top of the semiconductor structure 400a. In some implementations, the general type of dielectric layer or the high-K dielectric layer 401 can be deposited on top of the semiconductor structure 400a only in the low voltage region 333. In other words, the insulating layer 304 of the semiconductor structure 400b is still exposed in the high voltage region 331.

FIG. 4C illustrates a semiconductor structure 400c including a polysilicon layer 403. The semiconductor structure 400c can be formed by depositing the polysilicon layer 403 on top of the semiconductor structure 400b. That is, the polysilicon layer 403 can be stacked on the high-K dielectric layer 401. The polysilicon layer 403 can be in contact with the portions 401-1, 401-2, and 401-3 of the high-K dielectric layer 401 along the Z direction.

FIG. 4D illustrates a semiconductor structure 400d, which can be formed by partially removing (e.g., by etching) the polysilicon layer 403 and the high-K dielectric layer 401. In some implementations, the polysilicon layer 403 can be conductive (e.g., by doping it with an N-type dopant or a P-type dopant). As shown in FIG. 4D, a remaining portion of the polysilicon layer 403 includes a conductive layer 412a-1, a conductive layer 414a-1, a conductive layer 408a-1, and a conductive layer 410a-1. The conductive layer 412a-1 and the conductive layer 414a-1 are in the high voltage region 331. The conductive layer 408a-1 and the conductive layer 410a-1 are in the low voltage region 333. A remaining portion of the portion 401-1 of the high-K dielectric layer 401 can include a high-K layer 412a-2 and a high-K layer 414a-2. A remaining portion of the portion 401-2 of the high-K dielectric layer 401 can include a high-K layer 408a-2 (e.g., N-type). A remaining portion of the portion 401-3 of the high-K dielectric layer 401 can include a high-K layer 410a-2 (e.g., P-type). The conductive layer 412a-1 is in contact with the high-K layer 412a-2 (e.g., along the Z direction). The conductive layer 414a-1 is in contact with the high-K layer 414a-2 (e.g., along the Z direction). The conductive layer 408a-1 is in contact with the high-K layer 408a-2 (e.g., along the Z direction). The conductive layer 410a-1 is in contact with the high-K layer 410a-2 (e.g., along the Z direction).

FIG. 4E illustrates a semiconductor structure 400e, which can be formed by partially removing the insulating layer 304 in the high voltage region 331. A remaining portion of the insulating layer 304 in the high voltage region 331 can include a dielectric layer 412a-3 and a dielectric layer 414a-3 separate from each other (e.g., along the X direction). The dielectric layer 412a-3 is between and in contact with the high-K layer 412a-2 and the P-type well 330 along the Z direction. The dielectric layer 414a-3 is between and in contact with the high-K layer 414a-2 and the N-type well 332 along the Z direction. The conductive layer 412a-1, the high-K layer 412a-2, and the dielectric layer 412a-3 can form a gate structure 412a of a transistor formed later (e.g., the transistor 412 of FIG. 4F or 4G). The conductive layer 414a-1, the high-K layer 414a-2, and the dielectric layer 414a-3 can form a gate structure 414a of a transistor formed later (e.g., the transistor 414 of FIG. 4H). The conductive layer 408a-1 and the high-K layer 408a-2 can form a gate structure 408a of a transistor formed later (e.g., the transistor 408 of FIG. 4I). The conductive layer 410a-1 and the high-K layer 410a-2 can form a gate structure 410a of a transistor formed later (e.g., the transistor 410 of FIG. 4J).

FIGS. 4F-4J illustrate transistors that can be formed from the semiconductor structure 400e of FIG. 4E. For example, FIG. 4F illustrates an implementation of an N-type transistor 412 formed using the gate structure 412a. FIG. 4G illustrates another implementation of the N-type transistor 412 formed using the gate structure 412a. FIG. 4H illustrates an implementation of a P-type transistor 414 formed using the gate structure 414a. FIG. 4I illustrates an implementation of an N-type transistor 408 formed using the gate structure 408a. FIG. 4J illustrates an implementation of a P-type transistor 410 formed using the gate structure 410a. It is understood that the structures shown in FIGS. 4F-4J are for illustration purpose and are not intended to be construed in a limiting sense. In practice, the transistors 408, 410, 412, and 414 may have different structures from those shown in FIGS. 4F-4J, and any suitable fabrication process can be applied to the forming process of these transistors.

FIG. 4F illustrates an implementation of the N-type transistor 412 in an enlarged view of an area 450 of FIG. 4E. As shown in FIG. 4F, the N-type transistor 412 can be formed from the semiconductor structure 400e. For example, the N-type transistor 412 can include the gate structure 412a and a semiconductor body 412b. The semiconductor body 412b extends into the P-type well 330 along the Z direction and is in contact with the dielectric layer 412a-3. The semiconductor body 412b can have two terminals 412b-1 and 412b-2. The terminal 412b-1 is on a first side of the semiconductor body 412b, and the terminal 412b-2 is on a second side of the semiconductor body 412b. The first side of the semiconductor body 412b can be opposite to the second side of the semiconductor body 412b along the X direction. One of the terminals 412b-1 and 412b-2 can be a source terminal, and another of the terminals 412b-1 and 412b-2 can be a drain terminal. Each of the terminals 412b-1 and 412b-2 can include an N-type epitaxial layer 458, an N-type lightly doped structure 460, and an N-type lightly doped structure 462. The N-type epitaxial layers 458 can be formed in the insulating layer 304. Each N-type epitaxial layer 458 is in contact with a respective N-type lightly doped structure 460 along the Z direction. The N-type lightly doped structure 460 is in the N-type lightly doped structure 462, and the N-type lightly doped structure 462 is in the P-type well 430. The N-type lightly doped structure 460 and the N-type lightly doped structure 462 can be formed by any suitable doping methods, such as ion implantation. The N-type lightly doped structure 460 and the N-type lightly doped structure 462 can be referred to as lightly doped drains if they are part of a drain terminal and can be referred to as lightly doped sources if they are part of a source terminal. In some implementations, the gate structure 412a can be between dielectric spacers 464 (e.g., along the X direction). The N-type transistor 412 can be between two isolation structures 328 along the X direction. The two isolation structures 328 can separate the N-type transistor 412 from another transistor adjacent to the N-type transistor 412. The N-type transistor 412 of FIG. 4F is an implementation of the transistor 212 of FIG. 2. In some implementations, the N-type transistor 412 of FIG. 4F can be an HV transistor.

FIG. 4G illustrates another implementation of the N-type transistor 412 in the enlarged view of the area 450 of FIG. 4E. The N-type transistor 412 in FIG. 4G is similar to the N-type transistor 412 in FIG. 4F. As shown in FIG. 4G, the N-type transistor 412 can be formed from the semiconductor structure 400e. For example, the N-type transistor 412 can include the gate structure 412a and a semiconductor body 412b. The semiconductor body 412b extends into the P-type well 330 along the Z direction and is in contact with the dielectric layer 412a-3. The semiconductor body 412b can have two terminals 412b-1 and 412b-2. The terminal 412b-1 is on a first side of the semiconductor body 412b, and the terminal 412b-2 is on a second side of the semiconductor body 412b. The first side of the semiconductor body 412b can be opposite to the second side of the semiconductor body 412b along the X direction. One of the terminals 412b-1 and 412b-2 can be a source terminal, and another of the terminals 412b-1 and 412b-2 can be a drain terminal. Each of the terminals 412b-1 and 412b-2 can include an N-type epitaxial layer 458, an N-type lightly doped structure 460, and an N-type lightly doped structure 462. The N-type epitaxial layers 458 can be formed in the insulating layer 304. Each N-type epitaxial layer 458 is in contact with a respective N-type lightly doped structure 460 along the Z direction. The N-type lightly doped structure 460 is in the N-type lightly doped structure 462, and the N-type lightly doped structure 462 is in the P-type well 330. The N-type lightly doped structure 460 and the N-type lightly doped structure 462 can be formed by any suitable doping methods, such as ion implantation. The N-type lightly doped structure 460 and the N-type lightly doped structure 462 can be referred to as lightly doped drains if they are part of a drain terminal and can be referred to as lightly doped sources if they are part of a source terminal. In some implementations, the gate structure 412a can be between dielectric spacers 464 (e.g., along the X direction). The N-type transistor 412 can be between two isolation structures 328 along the X direction. The two isolation structures 328 can separate the N-type transistor 412 from another transistor adjacent to the N-type transistor 412. The N-type transistor 412 of FIG. 4G is another implementation of the transistor 212 of FIG. 2. In some implementations, the N-type transistor 412 of FIG. 4G can be an HV transistor.

In practice, the structures of the terminals 412b-1 and 412b-2 may vary in different implementations. In the example of FIG. 4F, a portion of the P-type well 330 can separate each of the terminals 412b-1 and 412b-2 from the adjacent isolation structure 328 (e.g., along the X direction). In addition, in the example of FIG. 4F, each N-type epitaxial layer 458 can be surrounded by the insulating layer 304 (e.g., the dielectric layer 412a-3). In contrast, in the example of FIG. 4G, each of the terminals 412b-1 and 412b-2 (e.g., the N-type lightly doped structures 460 and 462) can be in contact with the adjacent isolation structure 328 (e.g., along the X direction). In addition, in the example of FIG. 4G, the insulating layer 304 (e.g., the dielectric layer 412a-3) can be between the two N-type epitaxial layers 458 (e.g., along the X direction).

FIG. 4H illustrates an implementation of the P-type transistor 414 in an enlarged view of an area 452 of FIG. 4E. As shown in FIG. 4H, the P-type transistor 414 can be formed from the semiconductor structure 400e. For example, the P-type transistor 414 can include the gate structure 414a and a semiconductor body 414b. The semiconductor body 414b extends into the N-type well 332 along the Z direction and is in contact with the dielectric layer 414a-3 (e.g., a portion of the insulating layer 304). The semiconductor body 414b can have two terminals 414b-1 and 414b-2. The terminal 414b-1 is on a first side of the semiconductor body 414b, and the terminal 414b-2 is on a second side of the semiconductor body 414b. The first side of the semiconductor body 414b can be opposite to the second side of the semiconductor body 414b along the X direction. One of the terminals 414b-1 and 414b-2 can be a source terminal, and another of the terminals 414b-1 and 414b-2 can be a drain terminal. Each of the terminals 414b-1 and 414b-2 can include a P-type epitaxial layer 466 and a P-type lightly doped structure 468. The P-type epitaxial layer 466 is in contact with the P-type lightly doped structure 468 along the Z direction. The P-type lightly doped structure 468 is in the N-type well 332. The P-type lightly doped structure 468 can be formed by any suitable doping methods, such as ion implantation. The P-type lightly doped structure 468 can be referred to as a lightly doped drain if it is part of a drain terminal and can be referred to as a lightly doped source if it is part of a source terminal. In some implementations, the gate structure 414a can be between dielectric spacers 464. The P-type transistor 414 can be between two isolation structures 328 along the X direction. The two isolation structures 328 can separate the P-type transistor 414 from another transistor adjacent to the P-type transistor 414. The P-type transistor 414 of FIG. 4H is an implementation of the transistor 214 of FIG. 2. In some implementations, the P-type transistor 414 of FIG. 4H can be an HV transistor.

FIG. 4I illustrates an implementation of the N-type transistor 408 in an enlarged view of an area 454 of FIG. 4E. As shown in FIG. 4I, the N-type transistor 408 can be formed from the semiconductor structure 400e. For example, the N-type transistor 408 can include the gate structure 408a and a semiconductor body 408b. The semiconductor body 408b is in contact with the insulating layer 304. The semiconductor body 408b can have two terminals 408b-1 and 408b-2. The terminal 408b-1 is on a first side of the semiconductor body 408b, and the terminal 408b-2 is on a second side of the semiconductor body 408b. The first side of the semiconductor body 408b can be opposite to the second side of the semiconductor body 408b along the X direction. One of the terminals 408b-1 and 408b-2 can be a source terminal, and another of the terminals 408b-1 and 408b-2 can be a drain terminal. Each of the terminals 408b-1 and 408b-2 can include an N-type epitaxial layer 472 and an N-type lightly doped structure 474. The N-type epitaxial layer 472 is in contact with the N-type lightly doped structure 474 along the Z direction. Each N-type lightly doped structure 474 is in the semiconductor layer 306. The N-type lightly doped structure 474 can be formed by any suitable doping methods, such as ion implantation. The N-type lightly doped structure 474 can be referred to as a lightly doped drain if it is part of a drain terminal and can be referred to as a lightly doped source if it is part of a source terminal. In some implementations, the gate structure 408a can be isolated from the N-type epitaxial layer 472 by dielectric spacers 464 (e.g., along the X direction). The N-type transistor 408 can be between two isolation structures 328 along the X direction. The two isolation structures 328 can separate the N-type transistor 408 from another transistor adjacent to the N-type transistor 408. The N-type transistor 408 of FIG. 4I is an implementation of the transistor 208 of FIG. 2. In some implementations, the N-type transistor 408 of FIG. 4I can be an LV transistor.

FIG. 4J illustrates an implementation of the P-type transistor 410 in an enlarged view of an area 456 of FIG. 4E. As shown in FIG. 4J, the P-type transistor 410 can be formed from the semiconductor structure 400e. For example, the P-type transistor 410 can include the gate structure 410a and a semiconductor body 410b. The semiconductor body 410b is in contact with the insulating layer 304. The semiconductor body 410b can have two terminals 410b-1 and 410b-2. The terminal 410b-1 is on a first side of the semiconductor body 410b, and the terminal 410b-2 is on a second side of the semiconductor body 410b. The first side of the semiconductor body 410b can be opposite to the second side of the semiconductor body 410b along the X direction. One of the terminals 410b-1 and 410b-2 can be a source terminal, and another of the terminals 410b-1 and 410b-2 can be a drain terminal. Each of the terminals 410b-1 and 410b-2 can include a P-type epitaxial layer 476 and a P-type lightly doped structure 478. The P-type epitaxial layer 476 is in contact with the P-type lightly doped structure 478 along the Z direction. Each P-type lightly doped structure 478 is in the semiconductor layer 306. The P-type lightly doped structure 478 can be formed by any suitable doping methods, such as ion implantation. The P-type lightly doped structure 478 can be referred to as a lightly doped drain if it is part of a drain terminal and can be referred to as a lightly doped source if it is part of a source terminal. In some implementations, the gate structure 410a can be isolated from the P-type epitaxial layer 476 by dielectric spacers 464 (e.g., along the X direction). The P-type transistor 410 can be between two isolation structures 328 along the X direction. The two isolation structures 328 can separate the P-type transistor 410 from another transistor adjacent to the P-type transistor 410. The P-type transistor 410 of FIG. 4J is an implementation of the transistor 210 of FIG. 2. In some implementations, the P-type transistor 410 of FIG. 4J can be an LV transistor.

In some implementations, the semiconductor devices or the semiconductor structures (e.g., the semiconductor devices 100 or 200, the semiconductor structures as shown in FIGS. 3J-3O and 4E-4J) described in the present disclosure can be a memory device, such as a three-dimensional (3D) NAND memory device or DRAM memory device. The memory device can include an array of memory cells and peripheral circuits configured to control the array of memory cells. The peripheral circuits can be formed using transistors (e.g., the transistors 108, 110, 112, 114, 208, 210, 212, 214, 308, 310, 312, 314, 408, 410, 412, and 414) described in the present disclosure.

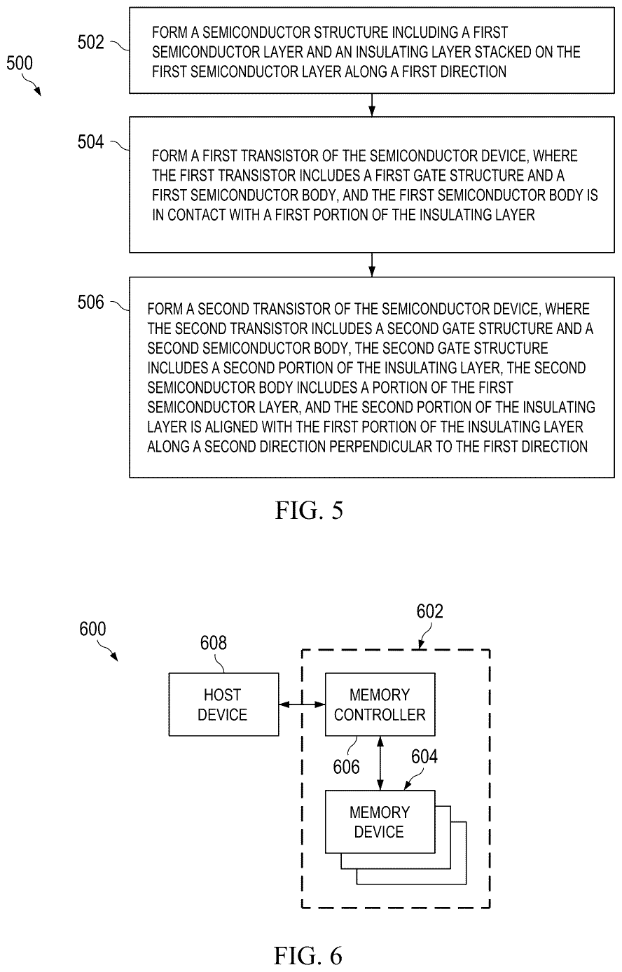

FIG. 5 illustrates a flow chart of an example method 500. The method 500 can be performed to form a semiconductor device (e.g., the semiconductor device 100 illustrated by FIG. 1 or the semiconductor device 200 illustrated by FIG. 2). The method 500 can be described in view of FIGS. 3A-3O and FIGS. 4A-4J. The method 500 can include one or more steps of the fabrication process of forming the semiconductor structures in FIGS. 3A-3O and FIGS. 4A-4J. It is understood that the operations shown in the method 500 are not exhaustive and that other operations can be performed as well before, after, or between any of the illustrated operations. Further, some of the operations may be performed simultaneously, or performed in a different order than that shown in FIG. 5.

At operation 502, a semiconductor structure (e.g., the semiconductor structure 300a of FIG. 3A) is formed. The semiconductor structure includes a first semiconductor layer (e.g., the semiconductor layer 302) and an insulating layer (e.g., the insulating layer 304) stacked on the first semiconductor layer along a first direction (e.g., the Z direction).

At operation 504, a first transistor (e.g., the transistor 308 of FIG. 3N or the transistor 408 of FIG. 4I) of the semiconductor device is formed. The first transistor includes a first gate structure (e.g., the gate structure 308a of FIG. 3N or the gate structure 408a of FIG. 4I) and a first semiconductor body (e.g., the semiconductor body 308b of FIG. 3N or the semiconductor body 408b of FIG. 4I). The first semiconductor body is in contact with a first portion (e.g., as shown in FIG. 3N or 4I) of the insulating layer (e.g., the insulating layer 304).

At operation 506, a second transistor (e.g., the transistor 312 of FIG. 3K or 3L or the transistor 412 of FIG. 4F or 4G) of the semiconductor device is formed. The second transistor includes a second gate structure (e.g., the gate structure 312a or 412a) and a second semiconductor body (e.g., the semiconductor body 312b or 412b). The second gate structure includes a second portion (e.g., the dielectric layer 312a-3 or 412a-3) of the insulating layer (e.g., the insulating layer 304). The second semiconductor body includes (e.g., as shown in FIGS. 3K, 3L, 4F, and 4G) a portion of the first semiconductor layer (e.g., the semiconductor layer 302). The second portion of the insulating layer is aligned with the first portion of the insulating layer along a second direction (e.g., the X direction) perpendicular to the first direction.

In some implementations, a size of the first portion of the insulating layer (e.g., the insulating layer 304) along the first direction is similar to or same as a size of the second portion (e.g., the dielectric layer 312a-3 or 412a-3) of the insulating layer along the first direction. The semiconductor structure (e.g., the semiconductor structure 300a) can further include a second semiconductor layer (e.g., the semiconductor layer 306) stacked on the insulating layer. The method 500 further includes forming a polysilicon layer (e.g., the polysilicon layer 348 of FIG. 3H or the polysilicon layer 403 of FIG. 4C) stacked over the insulating layer.

In some implementations, forming the first transistor (e.g., the transistor 308 or 408) includes forming a conductive layer (e.g., the conductive layer 308a-1 or 408a-1) of the first gate structure from a first portion of the polysilicon layer. Forming the first transistor further includes forming the first semiconductor body (e.g., the semiconductor body 308b of FIG. 3N or the semiconductor body 408b of FIG. 4I) from a first portion of the second semiconductor layer.

In some implementations, forming the second transistor (e.g., the transistor 312 or 412) includes forming a conductive layer (e.g., the conductive layer 312a-1 or 412a-1) of the second gate structure from a second portion of the polysilicon layer. Forming the second transistor further includes forming a dielectric layer (e.g., the dielectric layer 312a-3 or 412a-3) of the second gate structure from the second portion of the insulating layer. Forming the second transistor further includes forming the second semiconductor body (e.g., the semiconductor body 312b or 412b) from a portion of the first semiconductor layer.

In some implementations, the method 500 further includes depositing a high-K dielectric layer (e.g., the high-K dielectric layer 346 of FIG. 3F) in contact with the first portion of the second semiconductor layer. In some instances, e.g., as shown in FIG. 3H, forming the polysilicon layer stacked over the insulating layer includes depositing the polysilicon layer in contact with both a second portion (e.g., the region 344 of the semiconductor layer 306) of the second semiconductor layer and the high-K dielectric layer (e.g., the portions 346-1 and 346-2).

In some implementations, the method 500 further includes partially removing the polysilicon layer, the second semiconductor layer, and the high-K dielectric layer by an etching process (e.g., as shown in FIG. 3I). A remaining portion of the polysilicon layer includes the first portion (e.g., the conductive layer 308a-1) of the polysilicon layer and the second portion (e.g., the conductive layer 312a-1) of the polysilicon layer. A remaining portion of the second semiconductor layer includes the first portion (e.g., the N-type region 340) of the second semiconductor layer and the second portion (e.g., the semiconductive layer 312a-2) of the second semiconductor layer. The first gate structure further includes a dielectric layer (e.g., the dielectric layer 308a-2) that is in contact with the conductive layer of the first gate structure and is formed from a remaining portion of the high-K dielectric layer. The second gate structure further includes the second portion (e.g., the semiconductive layer 312a-2) of the second semiconductor layer between the second portion of the polysilicon layer and the second portion (e.g., the dielectric layer 312a-3) of the insulating layer.

In some implementations, the method 500 further includes removing a second portion (e.g., in the high voltage region 331) of the second semiconductor layer that is in contact with the second portion of the insulating layer (e.g., as shown in FIG. 4A). The method 500 further includes depositing a high-K dielectric layer (e.g., the high-K dielectric layer 401) in contact with both the second portion of the insulating layer and the first portion of the second semiconductor layer. In some instances, forming the polysilicon layer stacked over the insulating layer includes depositing the polysilicon layer on the high-K dielectric layer (e.g., as shown in FIG. 4C).

In some implementations, the method 500 further includes partially removing the polysilicon layer and the high-K dielectric layer by an etching process (e.g., as shown in FIG. 4D). A remaining portion of the polysilicon layer includes the first portion of the polysilicon layer (e.g., the conductive layer 408a-1) and the second portion of the polysilicon layer (e.g., the conductive layer 412a-1). A remaining portion of the high-K dielectric layer includes a first portion (e.g., the high-K layer 408a-2) of the high-K dielectric layer and a second portion (e.g., the high-K layer 412a-2) of the high-K dielectric layer. The first gate structure (e.g., the gate structure 408a) further includes a dielectric layer (e.g., the high-K layer 408a-2) that is in contact with the conductive layer of the first gate structure and is formed from the first portion of the high-K dielectric layer. The second gate structure (e.g., the gate structure 412a) further includes the second portion of the high-K dielectric layer (e.g., the high-K layer 412a-2) between the second portion of the polysilicon layer and the second portion of the insulating layer.

FIG. 6 illustrates a block diagram of an example system 600. The system 600 can have one or more semiconductor devices (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 6, the system 600 can include a host device 608 and a memory system 602 having one or more memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more memory devices 604.

A memory device 604 can include any semiconductor device disclosed in the present disclosure, such as the semiconductor device 100 as shown in FIG. 1 or the semiconductor device 200 as shown in FIG. 2. Memory controller 606 (a.k.a., a controller circuit) is coupled to memory device 604 and host device 608. Consistent with implementations of the present disclosure, memory device 604 can include a plurality of conductive interconnections through a cover layer that are in contact with conductive pads in a conductive pad layer, and memory controller 606 can be coupled to memory device 604 through at least one of the plurality of conductive interconnections. Memory controller 606 is configured to control memory device 604. For example, memory controller 606 may be configured to operate a plurality of channel structures via word lines. Memory controller 606 can manage data stored in memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of memory device 604, such as read, erase, and program (or write) operations. Memory controller 606 can also be configured to manage various functions with respect to the data stored or to be stored in memory device 604 including, but not limited to bad-block management, garbage collection, logical-to-physical address conversion, wear leveling, etc. In some implementations, memory controller 606 is further configured to process error correction codes (ECCs) with respect to the data read from or written to memory device 604. Any other suitable functions may be performed by memory controller 606 as well, for example, formatting memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g.,. +−0.10%,. +−0.20%, or. +−0.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a semiconductor layer;
an insulating layer stacked on the semiconductor layer along a first direction;
a first transistor comprising a first gate structure and a first semiconductor body, wherein the first semiconductor body is in contact with the insulating layer; and
a second transistor extending into the semiconductor layer along the first direction, wherein the second transistor comprises a second gate structure and a second semiconductor body, and the second gate structure comprises a dielectric layer aligned with the insulating layer along a second direction perpendicular to the first direction.

2. The semiconductor device of claim 1, wherein a size of the dielectric layer of the second gate structure along the first direction is similar to or same as a size of the insulating layer along the first direction.

3. The semiconductor device of claim 2, wherein a difference between the size of the dielectric layer of the second gate structure and the size of the insulating layer is smaller than a threshold.

4. The semiconductor device of claim 1, wherein the insulating layer has a first surface in contact with the first semiconductor body, the dielectric layer of the second gate structure has a first surface away from the second semiconductor body along the first direction, the first surface of the insulating layer is aligned with the first surface of the dielectric layer along the second direction.

5. The semiconductor device of claim 1, wherein the insulating layer has a second surface in contact with the semiconductor layer, the dielectric layer of the second gate structure has a second surface in contact with the second semiconductor body, the second surface of the insulating layer is aligned with the second surface of the dielectric layer along the second direction.

6. The semiconductor device of claim 1, wherein the insulating layer and the dielectric layer of the second gate structure comprises a same dielectric material.

7. The semiconductor device of claim 1, wherein the second gate structure further comprises a conductive layer and a doped silicon layer in contact with each other, the doped silicon layer is in contact with the dielectric layer of the second gate structure, and the doped silicon layer is between the conductive layer and the dielectric layer of the second gate structure along the first direction.

8. The semiconductor device of claim 7, wherein the conductive layer comprises polysilicon, and the doped silicon layer comprises silicon heavily doped using an N-type dopant.

9. The semiconductor device of claim 7, wherein the doped silicon layer has a surface in contact with the conductive layer, the first semiconductor body has a surface in contact with the first gate structure, the surface of the doped silicon layer is aligned with the surface of the first semiconductor body along the second direction.

10. The semiconductor device of claim 7, wherein a size of the doped silicon layer along the first direction is similar to or same as a size of the first semiconductor body along the first direction.

11. The semiconductor device of claim 1, wherein:
the first gate structure comprises a dielectric layer;
the semiconductor device further comprises a third transistor comprising a third gate structure and a third semiconductor body, wherein the third semiconductor body is in contact with the insulating layer, and the third gate structure comprises a dielectric layer;
a size of the dielectric layer of the second gate structure along the first direction is larger than a size of the dielectric layer of the first gate structure along the first direction; and
the size of the dielectric layer of the first gate structure along the first direction is larger than a size of the dielectric layer of the third gate structure along the first direction.

12. A semiconductor device, comprising:
a semiconductor layer;
an insulating layer stacked on the semiconductor layer along a first direction;
a first transistor comprising a first gate structure and a first semiconductor body, wherein the first semiconductor body is in contact with the insulating layer; and
a second transistor extending into the semiconductor layer along the first direction, wherein the second transistor comprises a second gate structure and a second semiconductor body, the second gate structure comprises a dielectric layer in contact with the second semiconductor body, and a size of the dielectric layer of the second gate structure along the first direction is similar to or same as a size of the insulating layer along the first direction.

13. The semiconductor device of claim 12, wherein a difference between the size of the dielectric layer of the second gate structure and the size of the insulating layer is smaller than 10% of the size of the insulating layer.

14. A method of forming a semiconductor device, comprising:
forming a semiconductor structure comprising a first semiconductor layer and an insulating layer stacked on the first semiconductor layer along a first direction;
forming a first transistor of the semiconductor device, wherein the first transistor comprises a first gate structure and a first semiconductor body, and the first semiconductor body is in contact with a first portion of the insulating layer; and
forming a second transistor of the semiconductor device, wherein the second transistor comprises a second gate structure and a second semiconductor body, the second gate structure comprises a second portion of the insulating layer, the second semiconductor body comprises a portion of the first semiconductor layer, the second portion of the insulating layer is aligned with the first portion of the insulating layer along a second direction perpendicular to the first direction.

15. The method of claim 14, wherein a size of the first portion of the insulating layer along the first direction is similar to or same as a size of the second portion of the insulating layer along the first direction, the semiconductor structure further comprises a second semiconductor layer stacked on the insulating layer, and the method further comprises:
forming a polysilicon layer stacked over the insulating layer.

16. The method of claim 15, wherein forming the first transistor comprises:
forming a conductive layer of the first gate structure from a first portion of the polysilicon layer; and
forming the first semiconductor body from a first portion of the second semiconductor layer,
and wherein forming the second transistor comprises:
forming a conductive layer of the second gate structure from a second portion of the polysilicon layer;
forming a dielectric layer of the second gate structure from the second portion of the insulating layer; and
forming the second semiconductor body from a portion of the first semiconductor layer.

17. The method of claim 16, further comprising:
depositing a high-K dielectric layer in contact with the first portion of the second semiconductor layer,
wherein forming the polysilicon layer stacked over the insulating layer comprises:
depositing the polysilicon layer in contact with both a second portion of the second semiconductor layer and the high-K dielectric layer.

18. The method of claim 17, further comprising:
partially removing the polysilicon layer, the second semiconductor layer, and the high-K dielectric layer by an etching process, wherein:
a remaining portion of the polysilicon layer comprises the first portion of the polysilicon layer and the second portion of the polysilicon layer;
a remaining portion of the second semiconductor layer comprises the first portion of the second semiconductor layer and the second portion of the second semiconductor layer;
the first gate structure further comprises a dielectric layer that is in contact with the conductive layer of the first gate structure and is formed from a remaining portion of the high-K dielectric layer; and
the second gate structure further comprises the second portion of the second semiconductor layer between the second portion of the polysilicon layer and the second portion of the insulating layer.

19. The method of claim 16, further comprising:
removing a second portion of the second semiconductor layer that is in contact with the second portion of the insulating layer; and
depositing a high-K dielectric layer in contact with both the second portion of the insulating layer and the first portion of the second semiconductor layer,
wherein forming the polysilicon layer stacked over the insulating layer comprises:
depositing the polysilicon layer on the high-K dielectric layer.

20. The method of claim 19, further comprising:
partially removing the polysilicon layer and the high-K dielectric layer by an etching process, wherein:
a remaining portion of the polysilicon layer comprises the first portion of the polysilicon layer and the second portion of the polysilicon layer;
a remaining portion of the high-K dielectric layer comprises a first portion of the high-K dielectric layer and a second portion of the high-K dielectric layer;
the first gate structure further comprises a dielectric layer that is in contact with the conductive layer of the first gate structure and is formed from the first portion of the high-K dielectric layer; and
the second gate structure further comprises the second portion of the high-K dielectric layer between the second portion of the polysilicon layer and the second portion of the insulating layer.
